(19) United States
(12) Patent Application Publication
(10) Pub. No.: US 2026/0073955 A1
(43) Pub. Date: Mar. 12, 2026

(54) VERTICAL NONVOLATILE MEMORY DEVICE

(71) Applicant: Samsung Electronics Co., Ltd., Suwon-si (KR)

(72) Inventors: Byungchul LEE, Suwon-si (KR); Joonyoung KWON, Suwon-si (KR); Wonjin KIM, Suwon-si (KR); Junhyoung KIM, Suwon-si (KR); Jiyoung KIM, Suwon-si (KR); Sukkang SUNG, Suwon-si (KR); Hyeonpil JOO, Suwon-si (KR)

(73) Assignee: Samsung Electronics Co., Ltd., Suwon-si (KR)

(21) Appl. No.: 19/212,973

(22) Filed: May 20, 2025

(30) Foreign Application Priority Data
Sep. 11, 2024 (KR) 10-2024-0124243

(51) Int. Cl. G11C 5/06; G11C 16/04; H10B 43/10; H10B 43/27; H10B 43/35

(52) U.S. Cl. CPC G11C 5/063; G11C 16/0483; H10B 43/10; H10B 43/27; H10B 43/35

(57) ABSTRACT

A vertical nonvolatile memory device includes vertical channel structures, first gate lines extending in a horizontal direction while surrounding the vertical channel structures and apart from each other in a vertical direction, a second gate line extending in the horizontal direction on the first gate lines, a first semiconductor line of a first conductivity type and extending in the horizontal direction on the second gate line, semiconductor contact plugs of a second conductivity type and connected to the vertical channel structures by passing through the first semiconductor line and the second gate line, a second semiconductor line of a second conductivity type extending in the horizontal direction on the semiconductor contact plugs and connected to the semiconductor contact plugs, a first metal contact plug connected to the first semiconductor line, and a second metal contact plug connected to the second semiconductor line.

### CROSS-REFERENCE TO RELATED APPLICATION

This application is based on and claims priority under 35 U.S.C. § 119 to Korean Patent Application No. 10-2024-0124243, filed on Sep. 11, 2024, in the Korean Intellectual Property Office, the disclosure of which is incorporated by reference herein in its entirety.

### BACKGROUND

Inventive concepts relate to a memory device, and more particularly, to a vertical nonvolatile memory device.

Nonvolatile memory devices capable of storing high capacity data have been demanded in an electronic system with respect to which data storage is required. Thus, methods of increasing the data storage capacity of a nonvolatile memory device have been researched. For example, as one of the methods of increasing the data storage capacity of the nonvolatile memory device, vertical nonvolatile memory devices including three-dimensionally arranged vertical memory cells rather than two-dimensionally arranged memory cells have been proposed.

### SUMMARY

Inventive concepts provide a vertical nonvolatile memory device, in which operation characteristics of three-dimensionally arranged vertical memory cells are improved.

According to an example embodiment of inventive concepts, a vertical nonvolatile memory device may include a plurality of vertical channel structures extending in a vertical direction and apart from each other in a horizontal direction; a plurality of first gate lines extending in the horizontal direction while surrounding the plurality of vertical channel structures, the plurality of first gate lines being apart from each other in the vertical direction, the plurality of first gate lines being configured as word lines; a second gate line extending in the horizontal direction on the plurality of first gate lines, the second gate line being configured as a ground selection line; a first semiconductor line of a first conductivity type, the first semiconductor line extending in the horizontal direction on the second gate line; a plurality of semiconductor contact plugs of a second conductivity type, the plurality of semiconductor contact plugs being connected to the plurality of vertical channel structures by passing through the first semiconductor line and the second gate line; a second semiconductor line of a second conductivity type, the second semiconductor line extending in the horizontal direction on the plurality of semiconductor contact plugs and being connected to the plurality of semiconductor contact plugs; a first metal contact plug connected to the first semiconductor line; and a second metal contact plug connected to the second semiconductor line.

According to an example embodiment of inventive concepts, a vertical nonvolatile memory device may include a plurality of vertical channel structures extending in a vertical direction and apart from each other in a horizontal direction; a plurality of first gate lines extending in the horizontal direction while surrounding the plurality of vertical channel structures, the plurality of first gate lines being apart from each other in the vertical direction, and the plurality of first gate lines being configured as word lines; a second gate line extending in the horizontal direction on the plurality of first gate lines, the second gate line being configured as a ground selection line; a first semiconductor line of a first conductivity type, the first semiconductor line extending in the horizontal direction on the second gate line; a plurality of semiconductor contact plugs connected to the plurality of vertical channel structures by passing through the first semiconductor line and the second gate line, and the plurality of semiconductor contact plugs not doped with impurities; a first metal contact plug connected to the first semiconductor line; and a metal line extending in the horizontal direction on the plurality of semiconductor contact plugs and connected to the plurality of semiconductor contact plugs.

According to an example embodiment of inventive concepts, a vertical nonvolatile memory device may include a plurality of vertical channel structures extending in a vertical direction and spaced apart from each other in a horizontal direction; a plurality of first gate lines extending in the horizontal direction while surrounding the plurality of vertical channel structures, the plurality of first gate lines being apart from each other in the vertical direction, and the plurality of first gate lines being configured as word lines; a second gate line extending in the horizontal direction on the plurality of first gate lines, the second gate line being spaced apart from the plurality of vertical channel structures in the vertical direction and configured as a ground selection line; a first semiconductor line of a first conductivity type, the first semiconductor line extending in the horizontal direction on the second gate line, the first semiconductor line including a first ohmic contact region; a plurality of semiconductor contact plugs of a second conductivity type, the plurality of semiconductor contact plugs connected to the plurality of vertical channel structures by passing through the first semiconductor line and the second gate line; a gate dielectric layer of a ground selection transistor in a recess hole recessed toward a side wall of plurality of the semiconductor contact plugs, the recess hole being defined by a space between the side wall of the plurality of semiconductor contact plugs and the second gate line; a second semiconductor line of a second conductivity type, the second semiconductor line extending in the horizontal direction on the plurality of semiconductor contact plugs and being apart from the first semiconductor line in the vertical direction, the second semiconductor line being connected to the plurality of semiconductor contact plugs, the second semiconductor line including a second ohmic contact region; a first metal contact plug connected to the first semiconductor line through the first ohmic contact region; and a second metal contact plug connected to the second semiconductor line through the second ohmic contact region.

### BRIEF DESCRIPTION OF THE DRAWINGS

Embodiments will be more clearly understood from the following detailed description taken in conjunction with the accompanying drawings in which:

FIG. 1 is a block diagram of a vertical nonvolatile memory device according to an embodiment;

FIG. 2A is a schematic perspective view of the vertical nonvolatile memory device according to an embodiment;

FIG. 2B is an equivalent circuit diagram of a memory cell array of the vertical nonvolatile memory device according to an embodiment;

FIG. 3 is a layout diagram of main elements of a vertical nonvolatile memory device according to an embodiment;

FIG. 4 is a cross-sectional view of a vertical nonvolatile memory device according to an embodiment;

FIG. 5 is an enlarged partial cross-sectional view of FIG. 4;

FIG. 6 is a cross-sectional view of a vertical nonvolatile memory device according to an embodiment;

FIG. 7 is an enlarged partial cross-sectional view of FIG. 6;

FIGS. 8 to 28 are cross-sectional views to describe a method of manufacturing a vertical nonvolatile memory device, according to an embodiment; and

FIGS. 29 to 32 are cross-sectional views to describe a method of manufacturing a vertical nonvolatile memory device, according to an embodiment.

### DETAILED DESCRIPTION OF THE EMBODIMENTS

The notion that elements are “substantially the same” may indicate that the element may be completely the same and may also indicate that the elements may be determined to be the same in consideration of errors or deviations occurring during a process.

Hereinafter, embodiments will be described in detail by referring to the accompanying drawings. The embodiments described hereinafter may be realized as any one of the embodiments, and the embodiments described hereinafter may be realized as a combination of one or more of the embodiments. Thus, inventive concepts should not be interpreted as being limited to one embodiment. In this specification, drawings are illustrated in an exaggerated fashion to clearly describe inventive concepts.

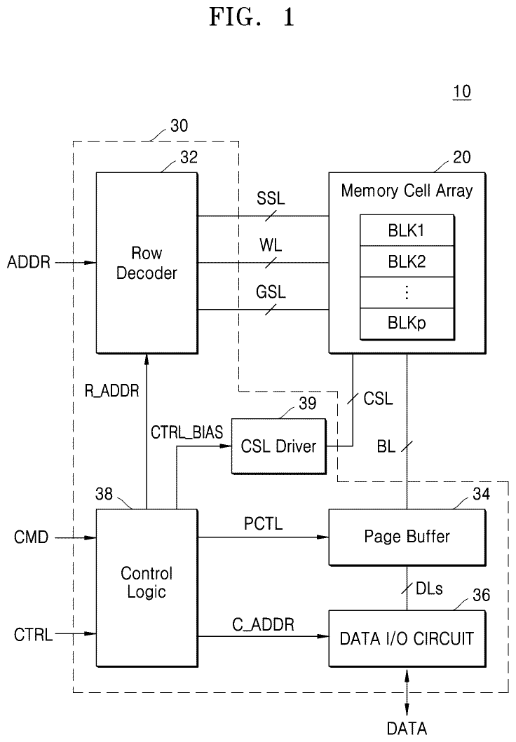

FIG. 1 is a block diagram of a vertical nonvolatile memory device 10 according to an embodiment.

In detail, the vertical nonvolatile memory device 10 may include a memory cell array 20 and a peripheral circuit 30. The memory cell array 20 may include a plurality of memory cell blocks BLK1, BLK2, . . . , and BLKp (p is a positive integer). Each of the plurality of memory cell blocks BLK1, BLK2, . . . , and BLKp may include a plurality of vertical memory cells. The plurality of memory cell blocks BLK1, BLK2, . . . , and BLKp may be connected to the peripheral circuit 30 through bit lines BL, word lines WL, string selection lines SSL, and ground selection lines GSL.

The peripheral circuit 30 may include a row decoder 32, a page buffer 34, a data input and output circuit 36, a control logic 38, and a common source line driver 39. The peripheral circuit 30 may further include a voltage generation circuit configured to generate various voltages necessary for operation of the vertical nonvolatile memory device 10, an error correction circuit configured to correct an error of data read from the memory cell array 20, and various circuits, such as an input and output interface.

The memory cell array 20 may be connected to the row decoder 32 through the word lines WL, the string selection lines SSL, and the ground selection lines GSL and may be connected to the page buffer 34 through the bit lines BL. In the memory cell array 20, the plurality of vertical memory cells included in each of the plurality of memory cell blocks BLK1, BLK2, . . . , and BLKp may include flash memory cells.

The memory cell array 20 may include a three-dimensional memory cell array. The three-dimensional memory cell array may include a plurality of NAND strings, and each NAND string may include a plurality of vertical memory cells connected to the plurality of word lines WL vertically stacked.

The peripheral circuit 30 may receive an address ADDR, a command CMD, and a control signal CTRL from the outside of the vertical nonvolatile memory device 10 and may transmit and receive data DATA to and from a device outside the vertical nonvolatile memory device 10.

The row decoder 32 may select at least one of the plurality of memory cell blocks BLK1, BLK2, . . . , and BLKp, in response to the address ADDR from the outside, and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit lines BL. The page buffer 34 may operate as a write driver during a program operation to apply, to the bit lines BL, a voltage according to data DATA to be stored in the memory cell array 20, and may operate as a sense amplifier during a read operation to sense data DATA stored in the memory cell array 20. The page buffer 34 may operate in response to a control signal PCTL provided from the control logic 38.

The data input and output circuit 36 may be connected to the page buffer 34 through a plurality of data lines DLs. During a program operation, the data input and output circuit 36 may receive data DATA from a memory controller (not shown) and based on a column address C_ADDR provided from the control logic 38, provide program data DATA to the page buffer 34. During a read operation, the data input and output circuit 36 may provide read data DATA stored in the page buffer 34 to the memory controller, based on a column address C_ADDR provided from the control logic 38.

The data input and output circuit 36 may transmit an input address or command to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and a column address C_ADDR to the data input and output circuit 36. The control logic 38 may generate, in response to the control signal CTRL, various internal control signals used in the vertical nonvolatile memory device 10. For example, the control logic 38 may control a voltage level provided to the word line WL and the bit line BL during a memory operation such as a program operation or an erase operation.

The common source line driver 39 may be connected to the memory cell array 20 through a common source line CSL. The common source line driver 39 may apply a common source voltage (for example, a power voltage) or a ground voltage to the common source line CSL, based on a bias control signal CTRL_BIAS of the control logic 38.

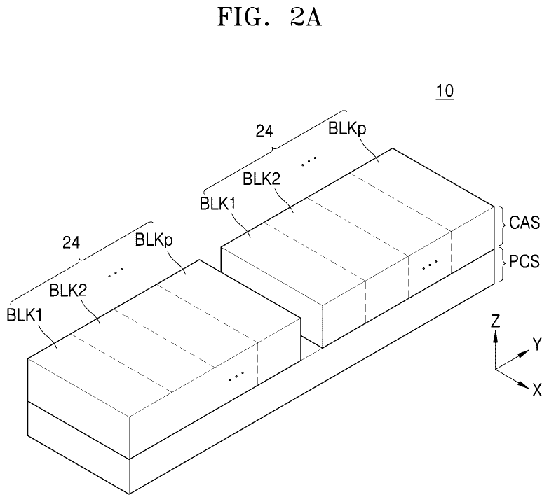

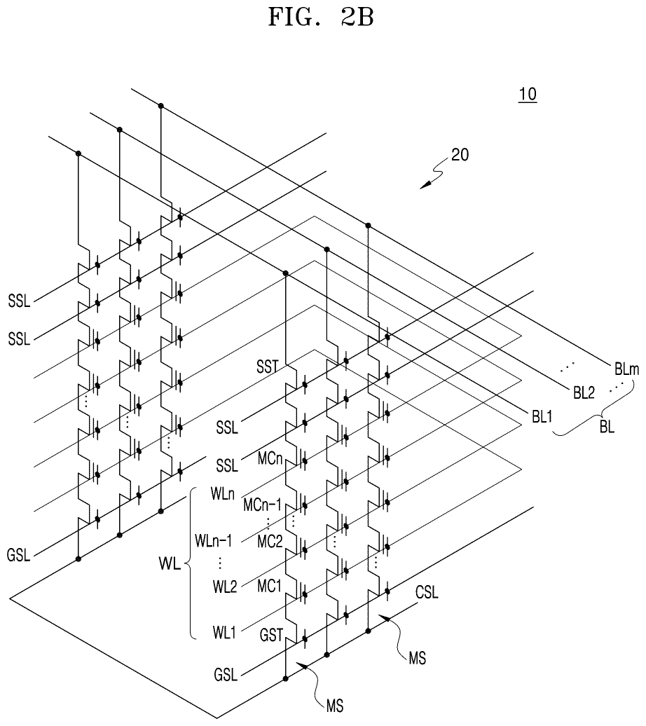

FIG. 2A is a schematic perspective view of the vertical nonvolatile memory device 10 according to an embodiment, and FIG. 2B is an equivalent circuit diagram of a memory cell array 20 of the vertical nonvolatile memory device 10 according to an embodiment.

Referring to FIG. 2A, the vertical nonvolatile memory device 10 may include a cell array structure CAS and a peripheral circuit structure PCS overlapping each other in a vertical direction (a Z direction). According to some embodiments, the vertical nonvolatile memory device 10 may include the cell array structure CAS and the peripheral circuit structure PCS bonded to each other in the vertical direction (the Z direction). For example, the cell array structure CAS may be formed on a first substrate (or a first wafer) and the peripheral circuit structure PCS may be formed on a second substrate (or a second wafer), and then, the first substrate and the second substrate may be bonded to each other to manufacture the vertical nonvolatile memory device 10.

The cell array structure CAS may include the memory cell array 20 described with reference to FIG. 1. The peripheral circuit structure PCS may include the peripheral circuit 30 described with reference to FIG. 1. The cell array structure CAS may include a plurality of tiles 24. Each of the plurality of tiles 24 may include a plurality of memory cell blocks BLK1, BLK2, . . . , and BLKp (p is a positive integer). Each of the plurality of memory cell blocks BLK1, BLK2, . . . , and BLKp may include a plurality of vertical memory cells that are three-dimensionally arranged.

According to some embodiments, two tiles 24 may form one mat, but inventive concepts are not limited thereto. The memory cell array 20 described with reference to FIG. 1 may include a plurality of mats, for example, four mats, but inventive concepts are not limited thereto.

Referring to FIG. 2B, the vertical nonvolatile memory device 10 may include the memory cell array 20 described with reference to FIG. 1. The memory cell array 20 may include a plurality of vertical memory cells. The vertical memory cells may be three-dimensionally arranged.

The vertical memory cells may include vertical NAND flash memory cells. The memory cell array 20 may include the plurality of memory cell blocks BLK1, BLK2, . . . , and BLKp illustrated in FIG. 1, each of which has a circuit structure illustrated in FIG. 2B.

The memory cell array 20 may include a plurality of memory cell strings MS. The memory cell array 20 may include a plurality of bit lines BL, for example, BL1, BL2, . . . , and BLm, a plurality of word lines WL, for example, WL1, WL2, . . . , WLn-1, and WLn, at least one string selection line SSL, at least one ground selection line GSL, and a common source line CSL. The plurality of memory cell strings MS may be formed between the plurality of bit lines BL and the common source line CSL.

FIG. 2B illustrates that each of the plurality of memory cell strings MS may include one ground selection line GSL and two string selection lines SSL. However, inventive concepts are not limited thereto. For example, each of the plurality of memory cell strings MS may include one ground selection line GSL and one string selection line SSL.

Each of the plurality of memory cell strings MS may include the vertical memory cells connected to each other in the vertical direction. Each of the plurality of memory cell strings MS may include a string selection transistor SST, a ground selection transistor GST, and a plurality of memory cell transistors MC1, MC2, . . . , MCn-1, and MCn. A drain area of the string selection transistor SST may be connected to the bit line BL, and a source area of the ground selection transistor GST may be connected to the common source line CSL. The common source line CSL may be an area to which source areas of the plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, . . . , MCn-1, and MCn may be connected to the plurality of word lines WL, that is, WL1, WL2, . . . , WLn-1, and WLn, respectively.

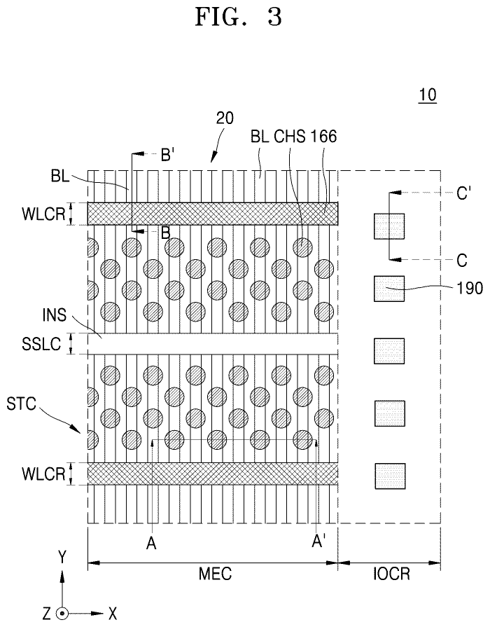

FIG. 3 is a layout diagram of main elements of the vertical nonvolatile memory device 10 according to an embodiment.

In detail, the vertical nonvolatile memory device 10 may include a memory cell area MEC. A memory cell array 20 may be formed in the memory cell area MEC. The memory cell area MEC may include a plurality of word line cut regions WLCR. The plurality of word line cut regions WLCR may extend lengthwise in a first horizontal direction (an X direction). The word line cut regions WLCR may be filled with a cut buried insulating layer 166. The first horizontal direction (the X direction) may correspond to a direction of the word lines WL of FIG. 2B.

The memory cell area MEC may include a string selection line cut region SSLC. The string selection line cut region SSLC may extend lengthwise in the first horizontal direction (the X direction). Two string selection lines SSL (see FIG. 2B) neighboring each other in a second horizontal direction (a Y direction) may be spaced apart from each other with the string selection line cut region SSLC therebetween. The string selection line cut region SSLC may be filled with an insulating layer INS.

The memory cell area MEC may include a plurality of vertical channel structures CHS passing through a stack structure STC in a vertical direction (a Z direction) and apart from each other in the first horizontal direction (the X direction) and the second horizontal direction (the Y direction). The stack structure STC may include a plurality of interlayer insulating layers or gate lines. The stack structure STC may be separated by the word line cut regions WLCR in the second horizontal direction (the Y direction).

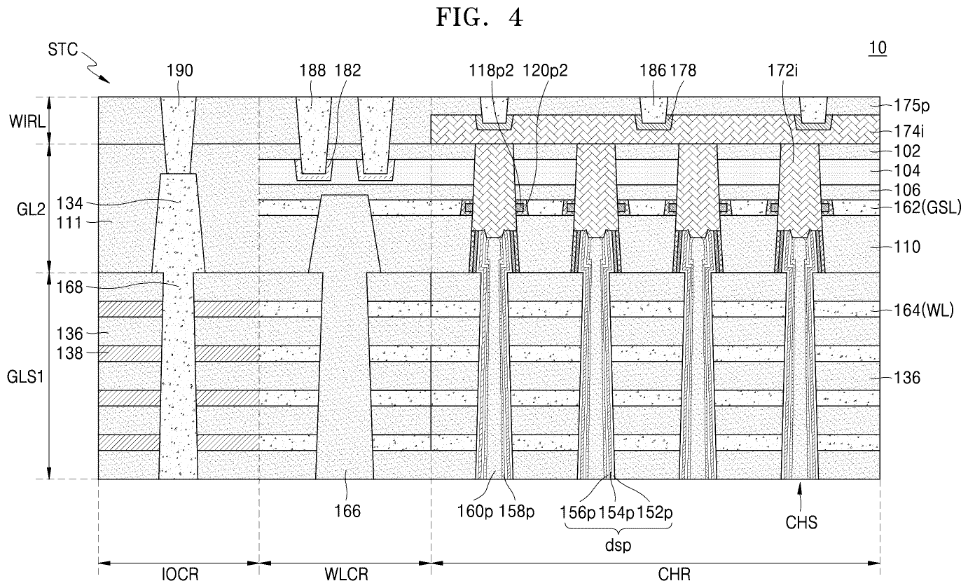

A region where the vertical channel structures CHS are arranged may be referred to as a channel region CHR (see FIG. 4). The channel region CHR may be defined by the word line cut regions WLCR. The vertical channel structures CHS may be located between the word line cut regions WLCR in the second horizontal direction (the Y direction).

A plurality of bit lines BL may be connected to the vertical channel structures CHS. The bit lines BL may extend in the second horizontal direction (the Y direction) and may be apart from each other in the first horizontal direction (the X direction). The plurality of bit lines BL may be connected to the vertical channel structures CHS below the vertical channel structures CHS. The second horizontal direction (the Y direction) may correspond to a direction of the bit lines BL of FIG. 2B.

The vertical nonvolatile memory device 10 may include an input and output contact region IOCR adjacent to the memory cell area MEC. The input and output contact region IOCR may include a plurality of input and output contact plugs (or input and output contact pads) 190. The input and output contact plugs 190 may be electrically connected to the peripheral circuit structure PCS included in the vertical nonvolatile memory device 10.

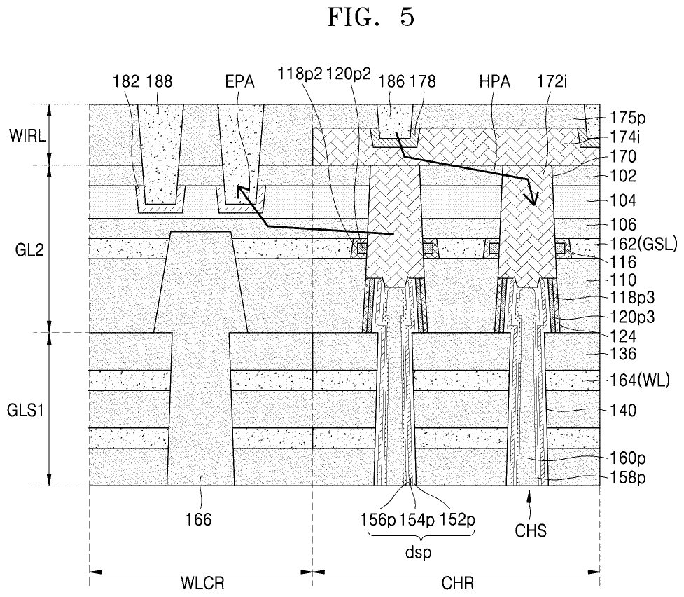

FIG. 4 is a cross-sectional view of the vertical nonvolatile memory device 10 according to an embodiment, and FIG. 5 is an enlarged partial cross-sectional view of FIG. 4.

In detail, the vertical nonvolatile memory device 10 may include the channel region CHR, the word line cut region WLCR, and the input and output contact region IOCR. The channel region CHR may correspond to a cross-section taken along line 'A-A' of FIG. 4. The word line cut region WLCR may correspond to a cross-section taken along line 'B-B' of FIG. 4. The input and output contact region IOCR may correspond to a cross-section taken along line 'C-C′ of FIG. 4.

In the channel region CHR, the plurality of vertical channel structures CHS, a plurality of first gate lines 164, a second gate line 162, a first semiconductor line 104 of a first conductivity type, a plurality of semiconductor contact plugs 172i of a second conductivity type, a second semiconductor line 174i of a second conductivity type, and a second metal contact plug 186 may be arranged. The channel region CHR may be defined by the word line cut regions WLCR.

The vertical channel structures CHS may extend in a vertical direction (a Z direction) and may be apart from each other in a horizontal direction (an X direction or a Y direction). The first gate lines 164 may extend in the horizontal direction (the X direction or the Y direction) while surrounding the vertical channel structures CHS and may be apart from each other in the vertical direction (the Z direction). The first gate lines 164 may be used as the word lines WL of FIG. 3.

The vertical channel structures CHS may include a data storage pattern dsp, a vertical channel pattern 158p, and a buried insulating pattern 160p that are sequentially formed at inner walls of channel holes 140 passing through the first gate lines 164 and a first interlayer insulating layer 136 in the vertical direction and first deformation stopper holes 124 formed in a third insulating layer 110. The data storage pattern dsp may include a tunnel insulating pattern 152p, a charge storage pattern 154p, and a blocking insulating pattern 156p sequentially formed at the inner walls of the channel holes 140 and the first deformation stopper holes 124.

The second gate line 162 may extend on the first gate lines 164, in the horizontal direction. The second gate line 162 may be used as the ground selection line GSL of FIG. 3. The first semiconductor line 104 may extend on the second gate line 162, in the horizontal direction. The first semiconductor line 104 may include a semiconductor layer of a first conductivity type, for example, N-type. The first semiconductor line 104 may include an N-type polysilicon layer.

The semiconductor contact plugs 172i may be connected to the vertical channel structures CHS by passing through the first semiconductor line 104 and the second gate line 162. The semiconductor contact plugs 172i may be buried in channel exposure holes 170 passing through the third insulating layer 110, the second gate line 162, a second insulating layer 106, the first semiconductor line 104, and a first insulating layer 102 on the vertical channel structures CHS.

The channel exposure holes 170 may expose upper surfaces of the vertical channel structures CHS. The channel exposure holes 170 may expose the data storage pattern dsp, the vertical channel pattern 158p, and the buried insulating pattern 160p which are included in the vertical channel structures CHS. The semiconductor contact plugs 172i may include a semiconductor layer of a second conductivity type, for example, P-type. The semiconductor contact plugs 172i may include a P-type polysilicon layer.

The second semiconductor line 174i may extend on the semiconductor contact plugs 172i, in the horizontal direction. The second semiconductor line 174i may be connected to the semiconductor contact plugs 172i. The second semiconductor line 174i may include a semiconductor layer of a second conductivity type, for example, P-type. The second semiconductor line 174i may include a P-type polysilicon layer. The second metal contact plug 186 may be connected to the second semiconductor line 174i.

Gate dielectric layers may be arranged between the semiconductor contact plugs 172i and the second gate line 162 in the channel region CHR. The gate dielectric layers 118p2 and 120p2 may be buried in a recess hole 116 recessed toward a side wall of the semiconductor contact plugs 172i. The gate dielectric layers may correspond to a gate dielectric layer of the ground selection transistor GST (see FIG. 2B).

The gate dielectric layers may include a first gate dielectric pattern 118p2 formed at an inner wall of the recess hole 116 and a second gate dielectric pattern 120p2 formed on the first gate dielectric pattern 118p2 in the recess hole 116. The second gate line 162 and the gate dielectric layers may be apart from the vertical channel structures CHS in the vertical direction.

A third gate dielectric pattern 118p3 and a fourth gate dielectric pattern 120p3 may be arranged at both sides of the upper portions of the vertical channel structures CHS in the channel region CHR. The third gate dielectric pattern 118p3 and the fourth gate dielectric pattern 120p3 may include the same materials as the first gate dielectric pattern 118p2 and the second gate dielectric pattern 120p2, respectively.

The cut buried insulating layer 166, a first ohmic contact region 182, and a first metal contact plug 188 may be arranged in the word line cut region WLCR. The cut buried insulating layer 166 may be buried in a word line cut hole 146 formed in the first gate lines 164, the second gate line 162, and the first interlayer insulating layer 136. The cut buried insulating layer 166 may include a silicon oxide layer.

The first semiconductor line 104 may extend in the horizontal direction from the channel region CHR to the word line cut region WLCR. The first metal contact plug 188 may be connected to the first semiconductor line 104 through the first ohmic contact region 182.

In the vertical nonvolatile memory device 10 according to inventive concepts, an electron path EPA between the first semiconductor line 104 and the first gate lines 164, that is, the word lines, may be formed during a read operation, as illustrated in FIG. 5. That is, when, during the read operation, a read voltage, for example, 7 V, is applied to the first semiconductor line 104 of the first conductivity type, that is, the N-type polysilicon layer, and 0 V is applied to the first gate lines 164, that is, the word lines, the electron path EPA to supply electrons to the first metal contact plug 188 and the first semiconductor line 104 from the first gate lines 164, that is, the word lines, through the semiconductor contact plugs 172i of the second conductivity type, that is, P-type, may be formed to increase read currents.

The second metal contact plug 186 connected to the second semiconductor line 174i may be arranged in the channel region CHR. The second metal contact plug 186 may be connected to the second semiconductor line 174i through the second ohmic contact region 178.

In the vertical nonvolatile memory device 10 according to inventive concepts, a hole path HPA between the second semiconductor line 174i and the first gate lines 164, that is, the word lines, may be formed during an erase operation, as illustrated in FIG. 5. That is, when, during the erase operation, an erase voltage, for example, 20 V, is applied to the second semiconductor line 174i of the second conductivity type, that is, the P-type polysilicon layer, and 0 V is applied to the first gate lines 164, that is, the word lines, the hole path EPA to supply holes to the first gate lines 164, that is, the word lines, from the second semiconductor line 174i, through the semiconductor contact plugs 172i of the second conductivity type, that is, P-type, may be formed to increase erase currents.

An input and output contact structure 168, a fourth buried layer 134, and an input and output contact plug (or an input and output pad) 190 may be arranged in the input and output contact region IOCR. The input and output contact structure 168 may be a metal layer buried in an input and output contact hole 148 formed in the first interlayer insulating layer 136 and a first interlayer sacrificial layer 138.

The fourth buried layer 134 may be connected to the input and output contact structure 168. The fourth buried layer 134 may include a metal layer. The fourth buried layer 134 may be formed in a fourth insulating layer 111. The input and output contact plug 190 may be connected to the fourth buried layer 134. The input and output contact plug 190 may be formed in a second interlayer insulating layer 175p and the fourth insulating layer 111.

The vertical nonvolatile memory device 10 may include the stack structure including, in the vertical direction, a first stack area GLS1, a second stack area GL2 arranged on the first stack area GLS1, and a wiring area WIRL arranged on the second stack area GL2.

The first stack area GSL1 may include the first gate lines 164 extending in the horizontal direction and a first portion of the vertical channel structures CHS passing through the first gate lines 164 in the vertical direction. The second stack area GL2 may include a second portion of the vertical channel structures CHS extending in the vertical direction from the first portion of the vertical channel structures CHS of the first stack area GLS1. In the first stack area GSL1, the input and output contact structure 168 may be formed in the first interlayer insulating layer 136 and the first interlayer sacrificial layer 138 in the input and the output contact region IOCR.

The second stack area GL2 may include the first semiconductor line 104 of the first conductivity type and extending in the horizontal direction and the plurality of semiconductor contact plugs 172i of the second conductivity type and passing through the first semiconductor line 104 and the second gate line 162 and connected to the second portion of the vertical channel structures CHS. The second stack area GL2 may include the fourth buried layer 134 connected to the input and output contact structure 168 of the input and output contact region IOCR.

The first stack area GSL1 and the second stack area GL2 may include the cut buried insulating layer 166 buried in the word line cut hole 146 passing through the first gate lines 164 and the second gate line 162 in the word line cut region WLCR.

The wiring area WIRL may include the second semiconductor line 174i of the second conductivity type, extending on the semiconductor contact plugs 172i of the channel region CHR in the horizontal direction, and connected to the semiconductor contact plugs 172i, the second metal contact plug 186 connected to the second semiconductor line 174i of the channel region CHR, and the first metal contact plug 188 connected to the first semiconductor line 104 of the word line cut region WLCR. The wiring area WIRL may include the input and output contact plug 190 connected to the fourth buried layer 134 of the input and output contact region IOCR.

The vertical nonvolatile memory device 10 having the structure as described above may include the semiconductor contact plugs 172i of the second conductivity type, that is, P-type, and connected to the vertical channel structures CHS in the vertical direction, and the second semiconductor line 174i extending on the semiconductor contact plugs 172i in the horizontal direction and including the polysilicon layer of the second conductivity type, that is, P-type. Thus, the vertical nonvolatile memory device 10 may have the hole path HPA between the second semiconductor line 174i and the first gate lines 164, that is, the word lines, during the erase operation to increase the erase currents.

In addition, the vertical nonvolatile memory device 10 according to inventive concepts may include the first semiconductor line 104 extending on the vertical channel structures CHS in the horizontal direction and including the polysilicon layer of the first conductivity type, that is, N-type. Thus, the vertical nonvolatile memory device 10 may have the electron path EPA between the first semiconductor line 104 and the first gate lines 164, that is, the word lines, during the read operation to increase the read currents. Consequently, in the vertical nonvolatile memory device 10 according to inventive concepts, operation characteristics of the three-dimensionally arranged vertical memory cells as described above may be improved.

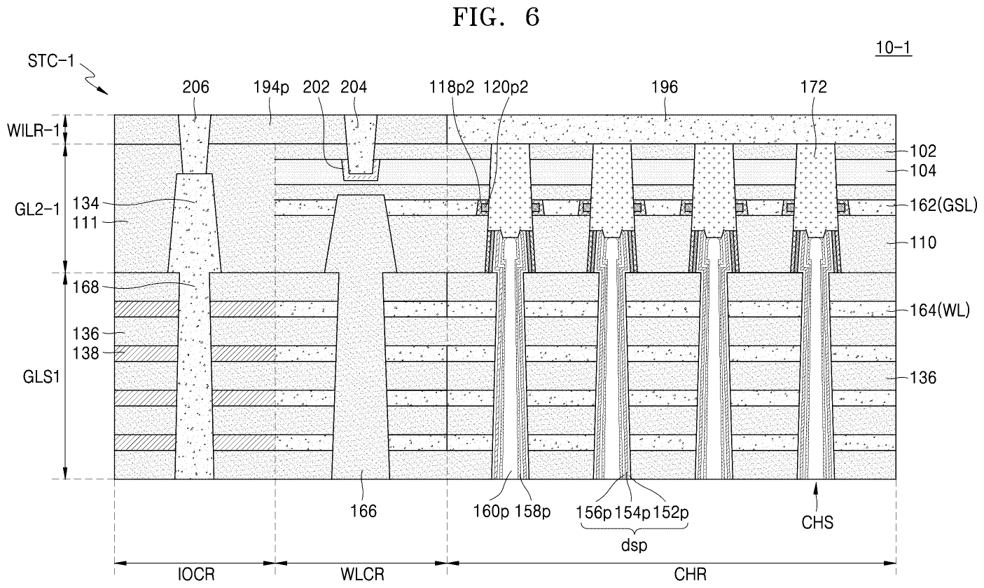

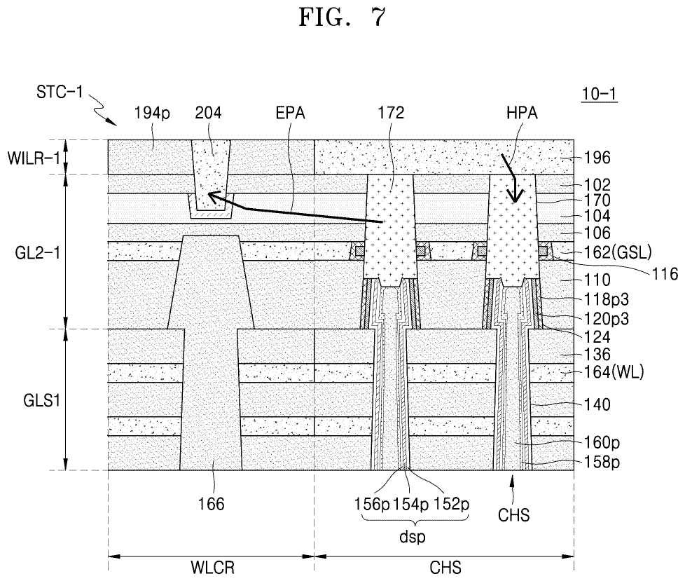

FIG. 6 is a cross-sectional view of a vertical nonvolatile memory device 10-1 according to an embodiment, and FIG. 7 is an enlarged partial cross-sectional view of FIG. 6.

In detail, the vertical nonvolatile memory device 10-1 may include the channel region CHR, the word line cut region WLCR, and the input and output contact region IOCR. The channel region CHR may correspond to a cross-section taken along line 'A-A' of FIG. 4. The word line cut region WLCR may correspond to a cross-section taken along line 'B-B' of FIG. 4. The input and output contact region IOCR may correspond to a cross-section taken along line 'C-C' of FIG. 4.

The vertical nonvolatile memory device 10-1 may be the same as the vertical nonvolatile memory device 10 of FIGS. 4 and 5, except for a difference in the configurations of a second stack area GL2-1 and a wiring area WIRL-1. Aspects of the vertical nonvolatile memory device 10-1 that are described with reference to FIGS. 4 and 5 are briefly described or are not described.

The vertical nonvolatile memory device 10-1 may include a stack structure STC-1 including, in a vertical direction, the first stack area GLS1, the second stack area GL2-1 arranged on the first stack area GLS1, and the wiring area WIRL-1 arranged on the second stack area GL2-1.

The second stack area GL2-1 may include the first semiconductor line 104 of the first conductivity type and extending in a horizontal direction and a plurality of semiconductor contact plugs 172 passing through the first semiconductor line 104 and the second gate line 162 and connected to the second portion of the vertical channel structures CHS. The semiconductor contact plugs 172 may include a semiconductor layer not doped with impurities.

The wiring area WIRL-1 may include a metal line 196 extending on the semiconductor contact plugs 172 of the channel region CHR in the horizontal direction and connected to the semiconductor contact plugs 172 and a third metal contact plug 204 connected to the first semiconductor line 104 of the word line cut region WLCR. The third metal contact plug 204 may be connected to the first semiconductor line 104 through a third ohmic contact region 202 of a first conductivity type, that is, N-type.

The wiring area WIRL-1 may include a fourth metal contact plug 206 connected to the fourth buried layer 134 of the input and output contact region IOCR. The wiring area WIRL-1 may include a third interlayer insulating layer 194p insulating the metal line 196, the third metal contact plug 204 and the fourth metal contact plug 206 from each other.

The vertical nonvolatile memory device 10-1 having the structure as described above may include the semiconductor contact plugs 172 not doped with impurities and connected to the vertical channel structures CHS in the vertical direction, and the metal line 196 extending on the semiconductor contact plugs 172 in the horizontal direction. As illustrated in FIG. 7, the vertical nonvolatile memory device 10-1 may have a hole path HPA between the metal line 196 and the first gate lines 164, that is, the word lines, during an erase operation.

That is, when, during the erase operation, an erase voltage, for example, 20 V, is applied to the metal line 196, and 0 V is applied to the first gate lines 164, that is, the word lines, the hole path HPA to supply holes to the first gate lines 164, that is, the word lines, from the metal line 196, through the semiconductor contact plugs 172 not doped with impurities, may be formed to increase erase currents.

In addition, in the vertical nonvolatile memory device 10-1 according to inventive concepts, the first semiconductor line 104 extending on the vertical channel structures CHS in the horizontal direction and including the polysilicon layer of the first conductivity type, that is, N-type, may be arranged. Thus, as illustrated in FIG. 7, the vertical nonvolatile memory device 10-1 may have an electron path EPA between the third metal contact plug 204 and the first gate lines 164, that is, the word lines, during a read operation, to increase read currents.

Consequently, in the vertical nonvolatile memory device 10-1 according to inventive concepts, operation characteristics of the three-dimensionally arranged vertical memory cells as described above may be improved.

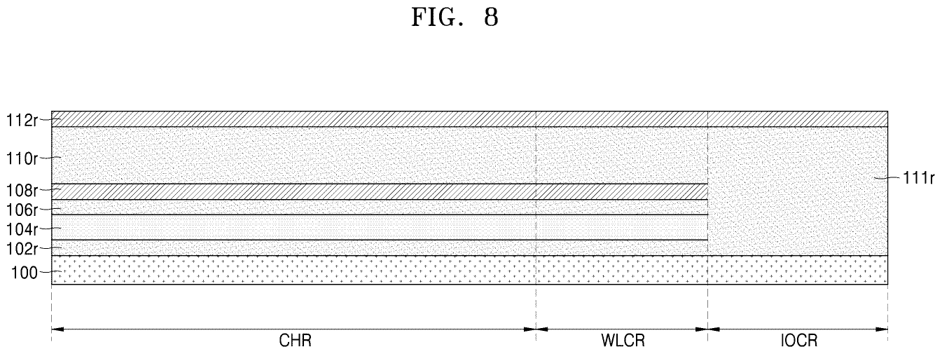

FIGS. 8 to 28 are cross-sectional views to describe a method of manufacturing a vertical nonvolatile memory device, according to an embodiment.

In detail, FIGS. 8 to 28 are cross-sectional views to describe the method of manufacturing the vertical nonvolatile memory device 10 of FIGS. 4 and 5. In FIGS. 8 to 28, the reference numerals that are the same or substantially the same as the reference numerals in FIGS. 4 and 5 indicate members that are the same or substantially the same as the members of FIGS. 4 and 5. In FIGS. 8 to 28, the aspects described with reference to FIGS. 4 and 5 are briefly described or are not described.

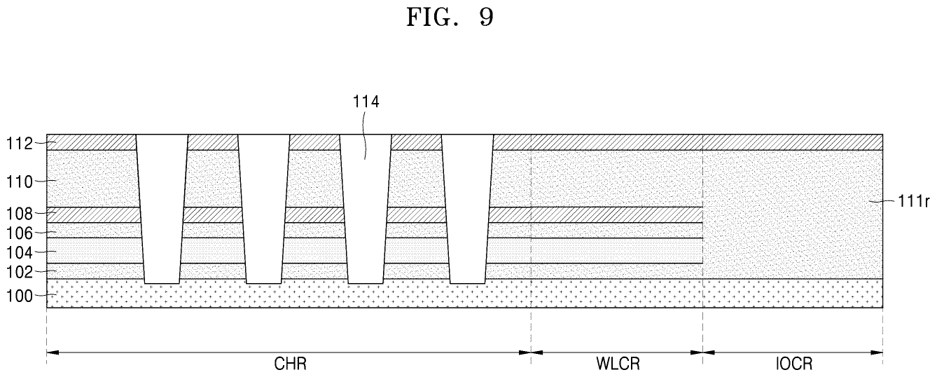

Referring to FIGS. 8 and 9, as illustrated in FIG. 8, a substrate 100 may be defined into the channel region CHR, the word line cut region WLCR, and the input and output contact region IOCR. The substrate 100 may include a semiconductor material. The substrate 100 may include a silicon monocrystalline substrate, a germanium monocrystalline substrate, or a silicon-germanium monocrystalline substrate.

A first insulating material layer 102r, a first semiconductor line material layer 104r, a second insulating material layer 106r, and a first sacrificial material layer 108r may be formed in the channel region CHR and the word line cut region WLCR of the substrate 100.

The first insulating material layer 102r, the first semiconductor line material layer 104r, the second insulating material layer 106r, and the first sacrificial material layer 108r may be formed to extend in a horizontal direction (the X direction or the Y direction of FIG. 4). The first insulating material layer 102r and the second insulating material layer 106r may include a silicon oxide layer. The first sacrificial material layer 108r may include a silicon nitride layer having an etch selectivity with respect to the silicon oxide layer. The first semiconductor line material layer 104r may include a semiconductor layer of a first conductivity type, for example, a polysilicon layer of N-type.

A third insulating material layer 110r and a fourth insulating material layer 111r may be respectively formed on the first sacrificial material layer 108r of the channel region CHR and the word line cut region WLCR and the substrate 100 of the input and output contact region IOCR. The fourth insulating material layer 111r may be formed to be thicker than the third insulating material layer 110r. The third insulating material layer 110r and the fourth insulating material layer 111r may include a silicon oxide layer.

A shield insulating material layer 112r may be formed on the third insulating material layer 110r and the fourth insulating material layer 111r. The shield insulating material layer 112r may be formed in the channel region CHR, the word line cut region WLCR, and the input and output contact region IOCR. The shield insulating material layer 112r may include a silicon nitride layer having an etch selectivity with respect to a silicon oxide layer.

As illustrated in FIG. 9, a plurality of first stopper holes 114 may be formed to be apart from each other in the channel region CHR. The first stopper holes 114 may be referred to as channel stopper holes. The first stopper holes 114 may be formed by selectively etching the shield insulating material layer 112r (see FIG. 8), the third insulating material layer 110r (see FIG. 8), the first sacrificial material layer 108r (see FIG. 8), the second insulating material layer 106r (see FIG. 8), the first semiconductor line material layer 104r (see FIG. 8), and the first insulating material layer 102r (see FIG. 8) of the channel region CHR, by using a photoetch process.

According to the formation of the first stopper holes 114, the shield insulating material layer 112r (see FIG. 8), the third insulating material layer 110r (see FIG. 8), the first sacrificial material layer 108r (see FIG. 8), the second insulating material layer 106r (see FIG. 8), the first semiconductor line material layer 104r (see FIG. 8), and the first insulating material layer 102r (see FIG. 8) may be a shield insulating layer 112, the third insulating layer 110, a first sacrificial layer 108, the second insulating layer 106, the first semiconductor line 104, and the first insulating layer 102, respectively.

According to the formation of the first stopper holes 114, a surface of the substrate 100 may be exposed. By forming the first stopper holes 114, a side wall SW1 of the shield insulating layer 112, the third insulating layer 110, the first sacrificial layer 108, the second insulating layer 106, the first semiconductor line 104, and the first insulating layer 102 may be exposed.

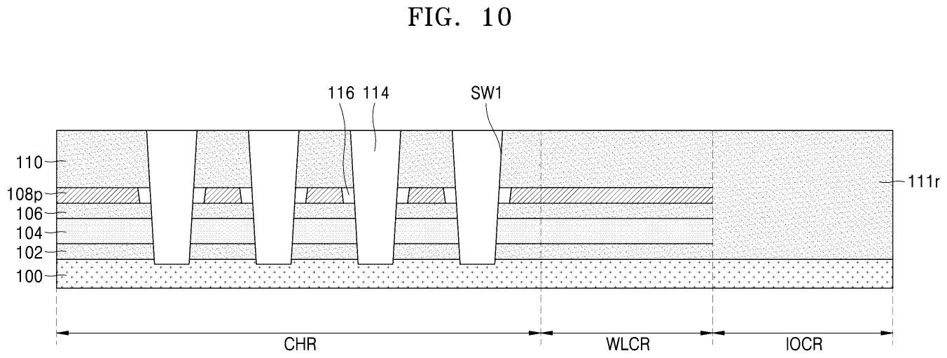

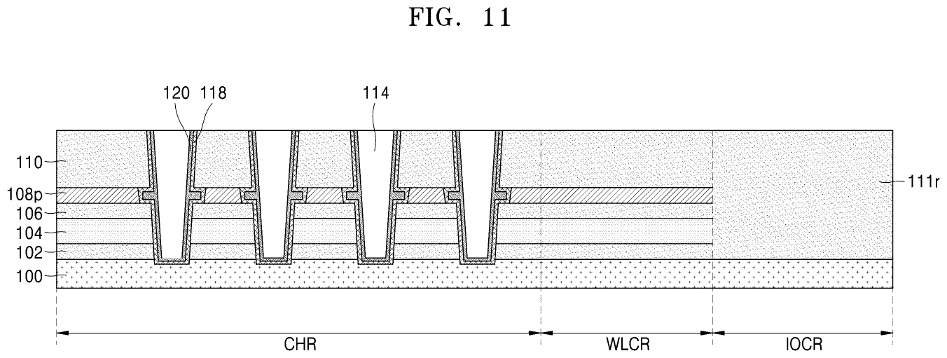

Referring to FIGS. 10 and 11, the shield insulating layer 112 may be etched and removed as illustrated in FIG. 10. According to some embodiments, the shield insulating layer 112 may be removed when the first stopper hoes 114 are formed. The first sacrificial layer 108 exposed by the first stopper holes 114 may be etched in the horizontal direction (the X direction) to form the recess hole 116.

The recess hole 116 may be connected to the first stopper holes 114. The recess hole 116 may be recessed inwardly from the side wall SW1 (see FIG. 10) of the first sacrificial layer 108. According to the formation of the recess hole 116, the first sacrificial layer 108 may be a first sacrificial pattern 108p.

As illustrated in FIG. 11, a first gate dielectric material layer 118 and a second gate dielectric material layer 120 may be sequentially formed in the first stopper holes 114 and the recess hole 116. The first gate dielectric material layer 118 may be formed on an inner wall and a bottom of the first stopper holes 114 and an inner wall of the recess hole 116. The second gate dielectric material layer 120 may be formed on the first gate dielectric material layer 118.

The second gate dielectric material layer 120 may also be formed in the first stopper holes 114. The first gate dielectric material layer 118 may include a material that is different from a material of the second gate dielectric material layer 120. The first gate dielectric material layer 118 may include a silicon oxide layer. The second gate dielectric material layer 120 may include a silicon nitride layer.

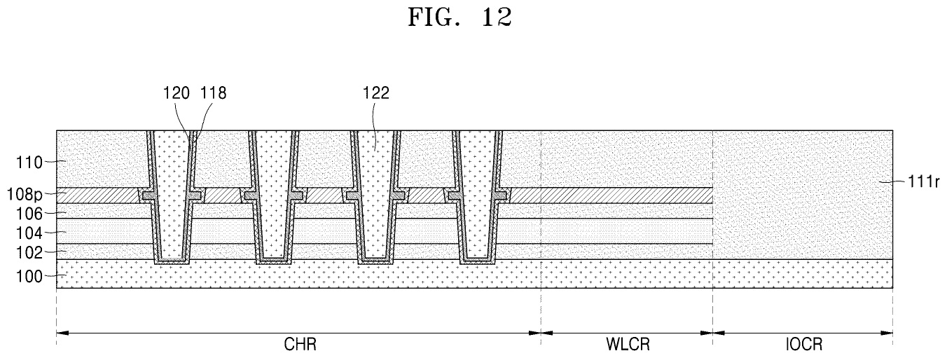

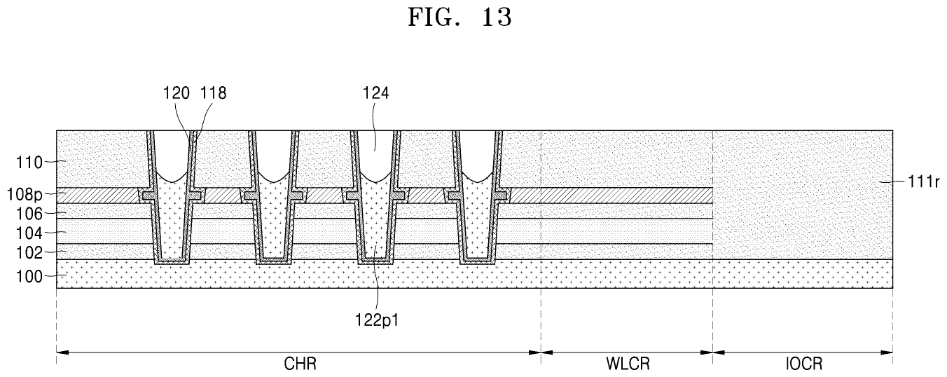

Referring to FIGS. 12 and 13, as illustrated in FIG. 12, first buried layers 122 buried in the first stopper holes 114 on the second gate dielectric material layer 120 may be formed. The first buried layers 122 may include polysilicon layers.

As illustrated in FIG. 13, the first buried layers 122 (see FIG. 12) may be etched back to form first buried patterns 122p1 in the first stopper holes 114. The first buried patterns 122p1 may be formed not to expose the first gate dielectric material layer 118 and the second gate dielectric material layer 120 formed in the recess hole 116 (see FIG. 10). By etching back the first buried layers 122, the first deformation stopper holes 124 may be formed in the first buried patterns 122p1.

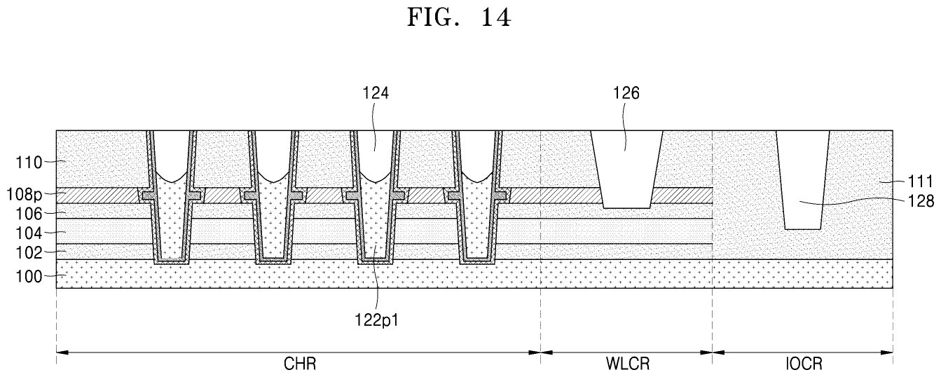

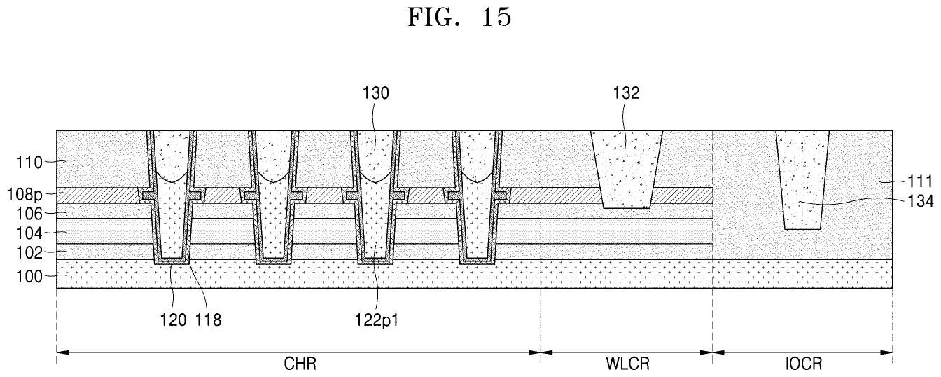

Referring to FIGS. 14 and 15, as illustrated in FIG. 14, a second stopper hole 126 and a third stopper hole 128 may be formed in the word line cut region WLCR and the input and output contact region IOCR, respectively. The second stopper hole 126 may be formed by selectively etching the third insulating layer 110 and the first sacrificial pattern 108p of the word line cut region WLCR by using a photoetch process.

The third stopper hole 128 may be formed by selectively etching the fourth insulating material layer 111r (see FIG. 13) of the input and output contact region IOCR by using a photoetch process. According to the formation of the third stopper hole 128, the fourth insulating material layer 111r (see FIG. 13) may be the fourth insulating layer 111.

As illustrated in FIG. 15, second buried layers 130 may be formed on the first buried patterns 122p1 exposed by the first deformation stopper holes 124 (see FIG. 14) of the channel region CHR. The second buried layers 130 may be formed to bury the first deformation stopper holes 124 (see FIG. 14) on the first buried patterns 122p1. The second buried layers 130 may include a metal layer, for example, a tungsten layer.

A third buried layer 132 and the fourth buried layer 134 may be formed to bury the second stopper hole 126 and the third stopper hole 128, respectively. The third buried layer 132 and the fourth buried layer 134 may include a metal layer, for example, a tungsten layer.

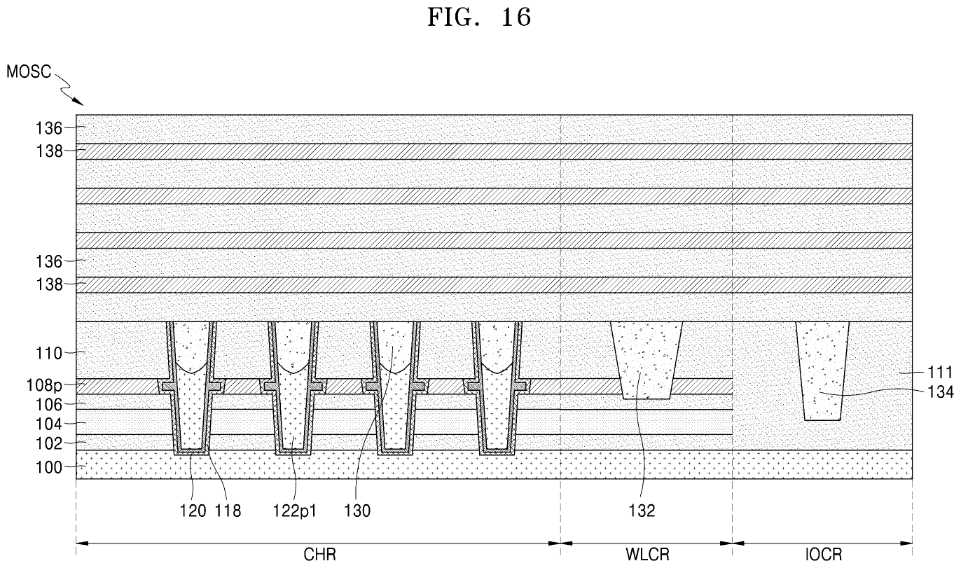

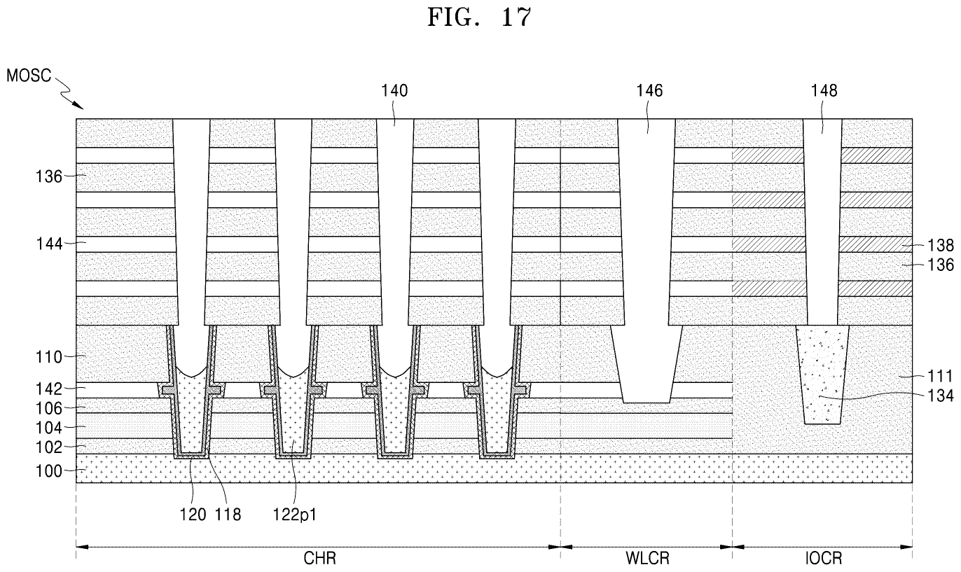

Referring to FIGS. 16 and 17, a mold structure MOSC may be formed in the channel region CHR, the word line cut region WLCR, and the input and output contact region IOCR as illustrated in FIG. 16. The mold structure MOSC may be formed on the third insulating layer 110 and the second buried layers 130 of the channel region CHR. The mold structure MOSC may be formed on the third insulating layer 110 and the third buried layer 132 of the word line cut region WLCR. The mold structure MOSC may be formed on the fourth buried layer 134 and the fourth insulating layer 111 of the input and output contact region IOCR.

The mold structure MOSC may be formed by alternately stacking the first interlayer insulating layer 136 and the first interlayer sacrificial layer 138 a plurality of times. The first interlayer insulating layer 136 may include a silicon oxide layer. The first interlayer sacrificial layer 138 may include a silicon nitride layer having an etch selectivity with respect to the first interlayer insulating layer 136.

As illustrated in FIG. 17, the channel holes 140 may be formed in the channel region CHR. The channel holes 140 may be formed by selectively etching the first interlayer insulating layer 136 and the first interlayer sacrificial layer 138 above the second buried layers 130 (see FIG. 16) and the second buried layers 130 (see FIG. 16) by using a photoetch process. According to the formation of the channel holes 140, the first buried patterns 122p1 may be exposed. According to the formation of the channel holes 140, the first deformation stopper holes 124 (see FIG. 14) may be exposed.

The word line cut hole 146 may be formed in the word line cut region WLCR. The word line cut hole 146 may be formed by selectively etching the first interlayer insulating layer 136, the first interlayer sacrificial layer 138, and the third buried layer 132 (see FIG. 16) by using a photoetch process. When the word line cut hole 146 is formed, the third buried layer 132 (see FIG. 16) may be sufficiently etched, and thus, the lower width of the word line cut hole 146 may be increased.

The input and output contact hole 148 may be formed in the input and output contact region IOCR. The input and output contact hole 148 may be formed by selectively etching the first interlayer insulating layer 136 and the first interlayer sacrificial layer 138 above the fourth buried layer 134 by using a photoetch process. According to the formation of the input and output contact hole 148, the fourth buried layer 134 may be exposed.

Furthermore, first horizontal holes 144 and a second horizontal hole 142 may be formed respectively by etching, in the horizontal direction, the first interlayer sacrificial layer 138 and the first sacrificial pattern 108p of the channel region CHR and the word line cut region WLCR.

The first horizontal holes 144 may be connected through the channel holes 140 and the word line cut hole 146. The first horizontal holes 144 may be spaced apart from each other in the vertical direction by the first interlayer insulating layer 136. The first horizontal holes 144 may not be formed in the input and output contact region IOCR. The second horizontal hole 142 may expose a side surface of the first gate dielectric material layer 118. The second horizontal hole 142 may be connected through the word line cut hole 146.

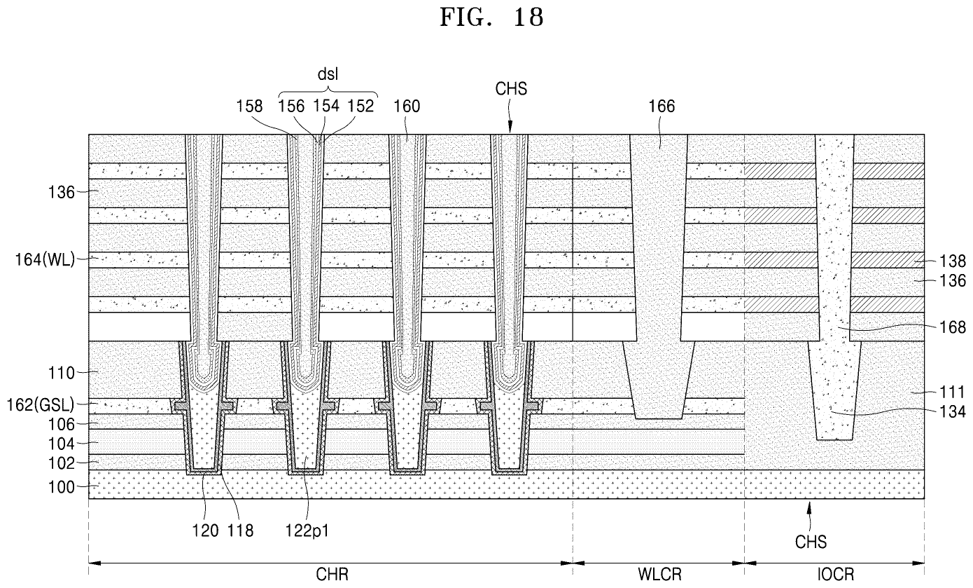

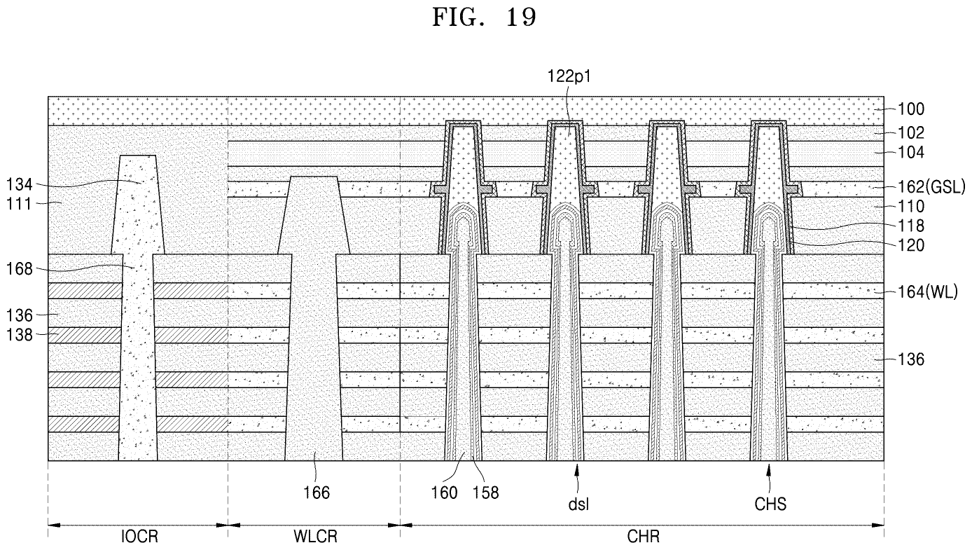

Referring to FIGS. 18 and 19, the vertical channel structures CHS may be formed in the channel holes 140 (see FIG. 17) and the first deformation stopper holes 124 (FIG. 14) of the channel region CHR, as illustrated in FIG. 18. The vertical channel structures CHS may include a data storage layer dsl, a vertical channel layer 158, and a buried insulating layer 160 sequentially formed on inner walls of the channel holes 140 (see FIG. 17) and the first deformation stopper holes 124 (see FIG. 14).

The data storage layer dsl may sequentially include a tunnel insulating layer 152, a charge storage layer 154, and a blocking insulating layer 156 on the inner walls of the channel holes 140 (see FIG. 17) and the first deformation stopper holes 124 (see FIG. 14). The tunnel insulating layer 152 may include a silicon oxide layer. The charge storage layer 154 may include a silicon nitride layer. The blocking insulating layer 156 may include a silicon oxide layer.

The vertical channel layer 158 may include a polysilicon layer or a monocrystalline silicon layer. The buried insulating layer 160 may bury the channel holes 140 (see FIG. 17) and the first deformation stopper holes 124 (see FIG. 14) on the vertical channel layer 158. The buried insulating layer 160 may include a silicon oxide layer. The cut buried insulating layer 166 may be formed in the word line cut hole 146 of the word line cut region WLCR. The cut buried insulating layer 166 may include a silicon oxide layer.

The first gate lines 164 may be formed by burying a metal layer, for example, a tungsten layer, in the first horizontal holes 144 (see FIG. 17) of the channel region CHR and the word line cut region WLCR. The first gate lines 164 may be used as the word lines.

The second gate line 162 may be formed by burying a metal layer, for example, a tungsten layer, in the second horizontal hole 142 (see FIG. 17) of the channel region CHR and the word line cut region WLCR. The second gate line 162 may be used as the ground selection line. The input and output contact structure 168 in contact with the fourth buried layer 134 may be formed by burying a metal layer, for example, a tungsten layer, in the input and output contact hole 148 of the input and output contact region IOCR.

Furthermore, a process of forming a bit line, a bit line pad, plugs connected to the first gate lines 164 (the word lines), a word line pad, etc. on the second gate line 162 of FIG. 18 may be performed.

As illustrated in FIG. 19, the structure of FIG. 18 is flipped. By doing so, the substrate 100 may be located above, and the first semiconductor line 104, the second gate line 162, and the first gate lines 164 may be located below the substrate 100. Also, the vertical channel structures CHS may be arranged below the substrate 100.

According to some embodiments, before flipping the structure of FIG. 18, a process of bonding the pad provided below the first gate lines 164, that is, the bit line pad or the word line pad, to a pad of a peripheral circuit structure, may be added.

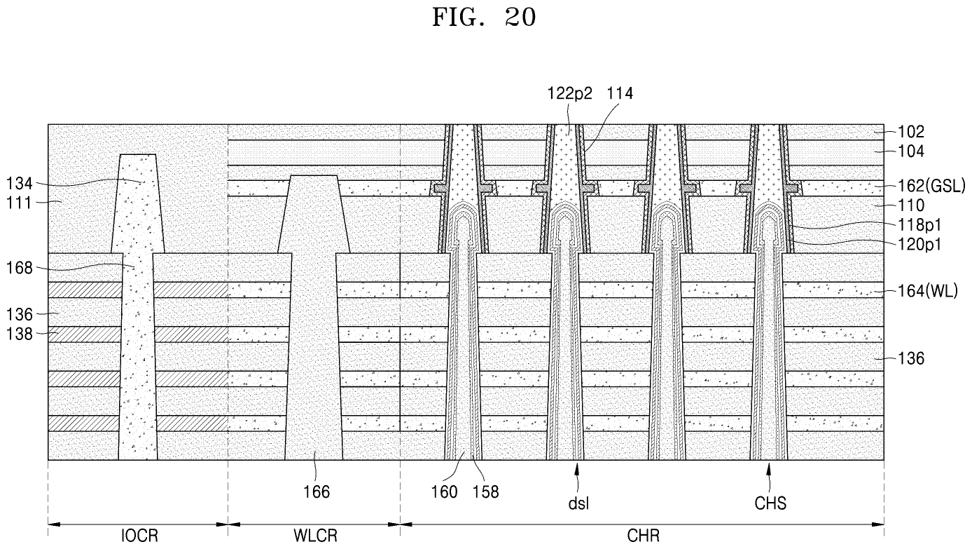

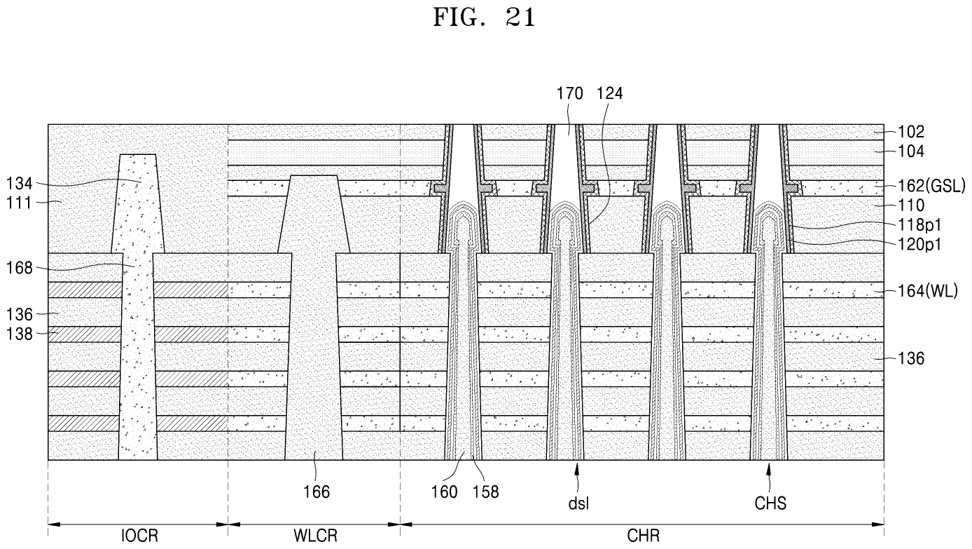

Referring to FIGS. 20 and 21, the substrate 100 (see FIG. 19) may be removed as illustrated in FIG. 20. Next, upper portions of the first gate dielectric material layer 118, the second gate dielectric material layer 120, and the first buried patterns 122p1 may be removed. The first gate dielectric material layer 118, the second gate dielectric material layer 120, and the first buried patterns 122p1 formed above the first stopper holes 114 formed in the channel region CHR may be removed.

By doing so, the first gate dielectric material layer 118 and the second gate dielectric material layer 120 may respectively be a first gate dielectric material layer 118p1 and a second gate dielectric material layer 120p1, upper portions of which are exposed. The first buried patterns 122p1 may be second buried patterns 122p2, upper portions of which are exposed.

As illustrated in FIG. 21, the second buried patterns 122p2 formed in the first stopper holes 114 may be etched by an etch process. By doing so, the channel exposure holes 170 exposing upper surfaces of the vertical channel structures CHS in the first deformation stopper holes 124 may be formed. The channel exposure holes 170 may expose a tunnel insulating layer included in the vertical channel structures CHS.

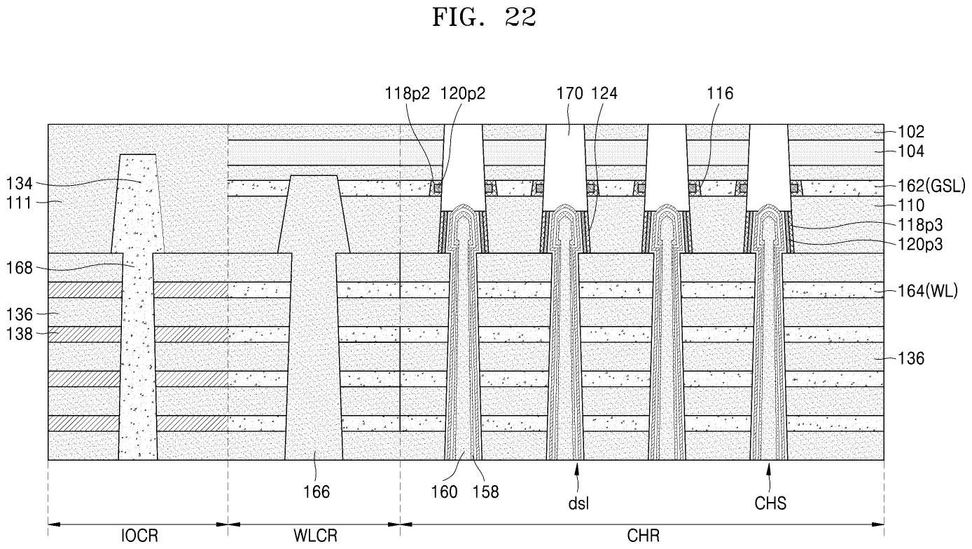

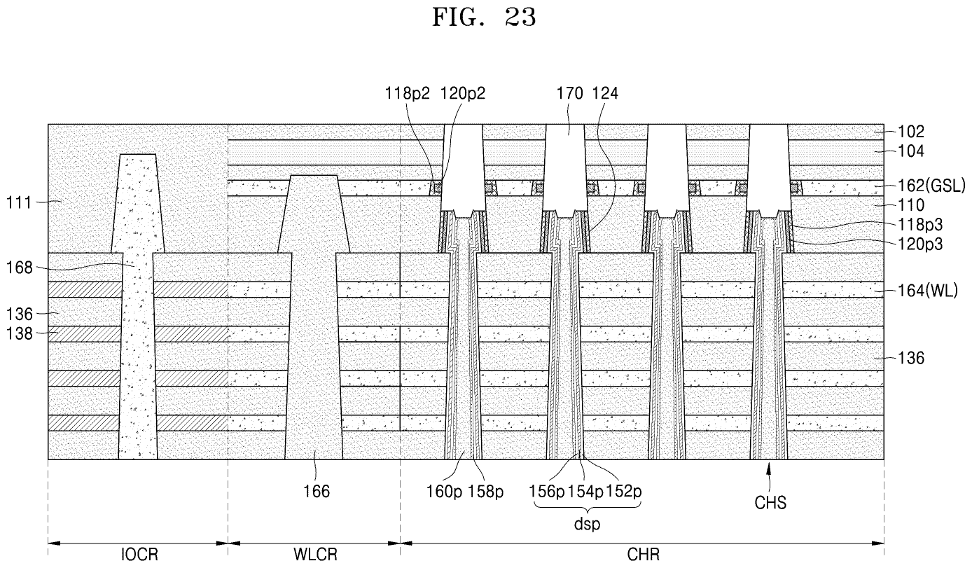

Referring to FIGS. 22 and 23, as illustrated in FIG. 22, the first gate dielectric material layer 118p1 (see FIG. 21) and the second gate dielectric material layer 120p1 (see FIG. 21) formed in the first stopper holes 114 at upper portions of the vertical channel structures CHS may be etched.

By doing so, the first gate dielectric material layer 118p1 (see FIG. 21) and the second gate dielectric material layer 120p1 (see FIG. 21) may respectively be the first gate dielectric pattern 118p2 buried in the recess hole 116 and the second gate dielectric pattern 120p2 formed on the first gate dielectric pattern 118p2 in the recess hole 116. The first gate dielectric pattern 118p2 and the second gate dielectric pattern 120p2 may be referred to as the gate dielectric layers 118p2 and 120p2, respectively. The gate dielectric layers 118p2 and 120p2 may be a gate dielectric layer of the ground selection transistor GST (see FIG. 2B).

Also, the first gate dielectric material layer 118p1 and the second gate dielectric material layer 120p1 may respectively be the third gate dielectric pattern 118p3 and the fourth gate dielectric pattern 120p3 arranged at both sides of the vertical channel structures CHS in the first deformation stopper holes 124.

As illustrated in FIG. 23, the upper surfaces of the vertical channel structures CHS exposed by the channel exposure holes 170 in the first deformation stopper holes 124 may be etched. Thus, the vertical channel structures CHS may include the data storage pattern dsp, the vertical channel pattern 158p, and the buried insulating pattern 160p sequentially formed on the inner walls of the channel holes 140 and the first deformation stopper holes 124.

The data storage pattern dsp may sequentially include the tunnel insulating pattern 152p, the charge storage pattern 154p, and the blocking insulating pattern 156p on the inner walls of the channel holes 140 and the first deformation stopper holes 124. The vertical channel pattern 158p included in the vertical channel structures CHS may be exposed by the channel exposure holes 170. The channel exposure holes 170 may expose the vertical channel pattern 158p by passing through the first semiconductor line 104 and the second gate line 162.

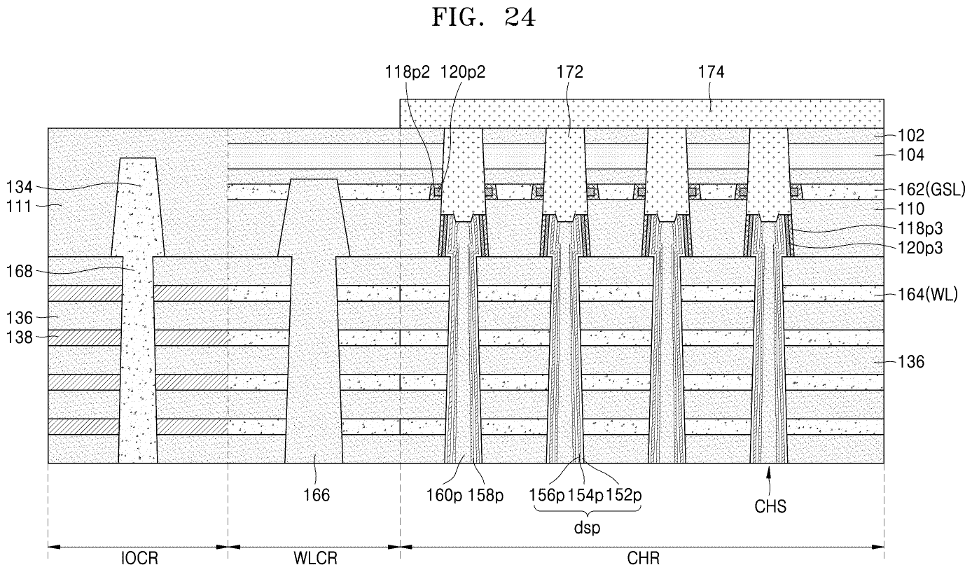

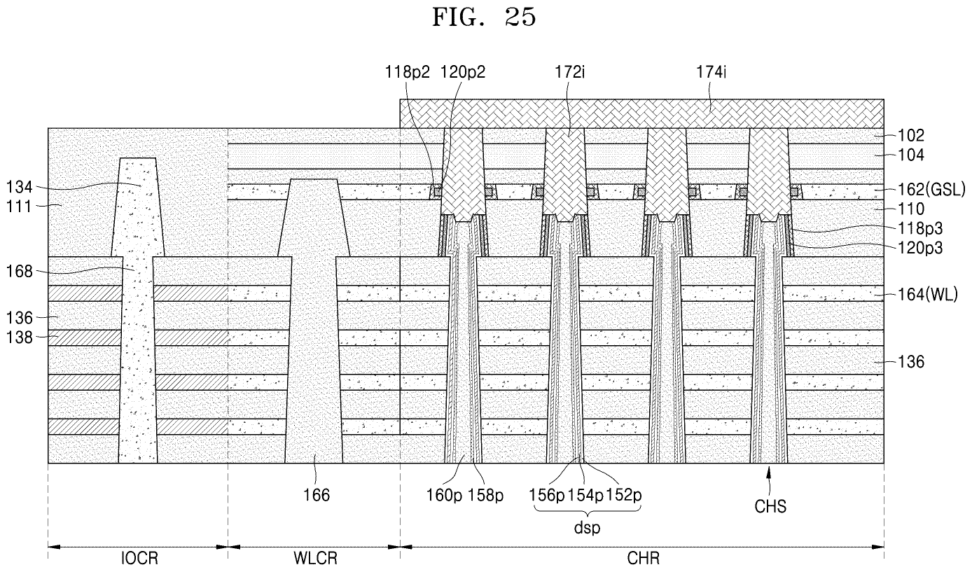

Referring to FIGS. 24 and 25, as illustrated in FIG. 24, the semiconductor contact plugs 172 buried in the channel exposure holes 170 on the vertical channel structure CHS may be formed. The semiconductor contact plugs 172 may be formed to be buried in the channel exposure holes 170 (see FIG. 23) passing through the first semiconductor line 104 and the second gate line 162.

Furthermore, a second semiconductor line 174 extending in the horizontal direction on the semiconductor contact plugs 172 and the first insulating layer 102 may be formed. The second semiconductor line 174 may be formed in the channel region CHR by forming a semiconductor material layer on the first insulating layer 102 of the channel region CHR, the word line cut region WLCR, and the input and output contact region IOCR and then patterning the semiconductor material layer by using a photoetch process. The semiconductor contact plugs 172 and the second semiconductor line 174 may include a polysilicon layer not doped with impurities.

As illustrated in FIG. 25, the semiconductor contact plugs 172 and the second semiconductor line 174 may be annealed by injecting impurities of a second conductivity type, for example, boron, which is P-type impurities. By doing so, the semiconductor contact plugs 172 and the second semiconductor line 174 may respectively be the semiconductor contact plugs 172i of the second conductivity type, that is, P-type, and the second semiconductor line 174i of the second conductivity type, that is, P-type.

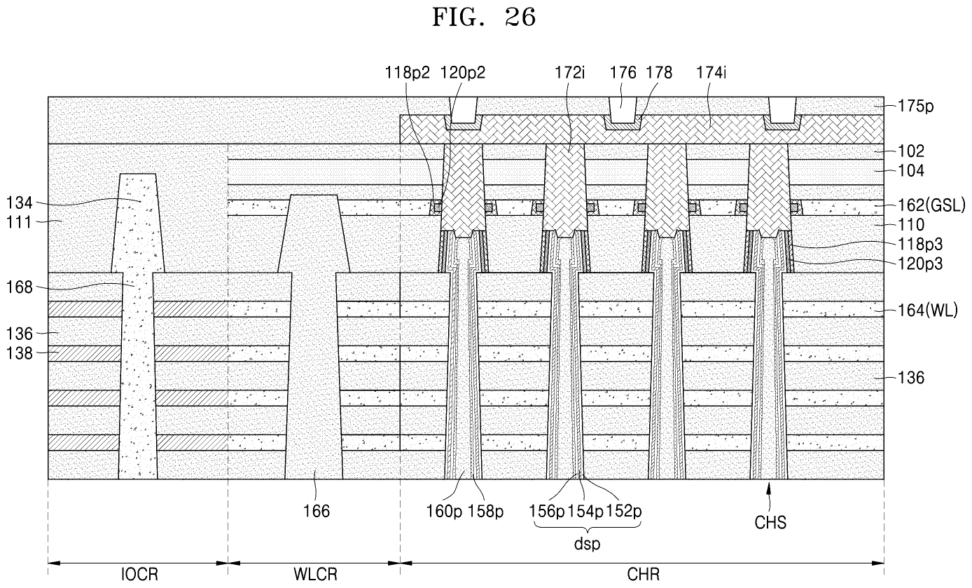

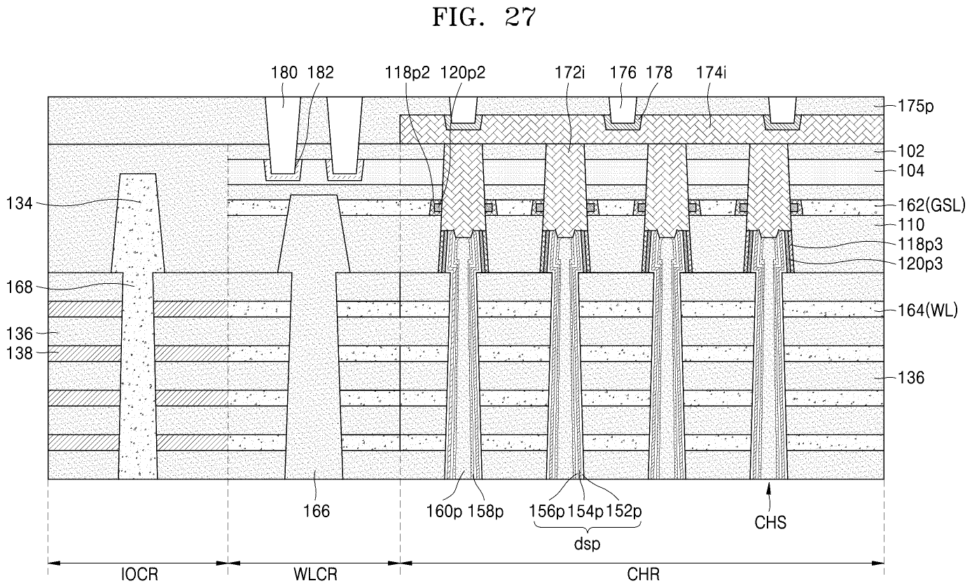

Referring to FIGS. 26 and 27, the second interlayer insulating layer 175p may be formed on the second semiconductor line 174i of the second conductivity type and the first insulating layer 102, as illustrated in FIG. 26. A second contact hole 176 exposing the second semiconductor line 174i of the second conductivity type may be formed in the second interlayer insulating layer 175p. Next, the second ohmic contact region 178 of the second conductivity type, that is, P-type, may be formed in the second contact hole 176. The second ohmic contact region 178 may be formed by injecting impurities of the second conductivity type, that is, P-type, in the second semiconductor line 174i of the second conductivity type in the second contact hole 176.

As illustrated in FIG. 27, a first contact hole 180 exposing the first semiconductor line 104 may be formed in the first insulating layer 102 arranged on the first semiconductor line 104 of the first conductivity type of the word line cut region WLCR and in the second interlayer insulating layer 175p.

Next, the first ohmic contact region 182 of the first conductivity type, that is, N-type, may be formed in the first contact hole 180. The first ohmic contact region 182 may be formed by injecting impurities of the first conductivity type, that is, N-type, in the first semiconductor line 104 of the first conductivity type in the first contact hole 180.

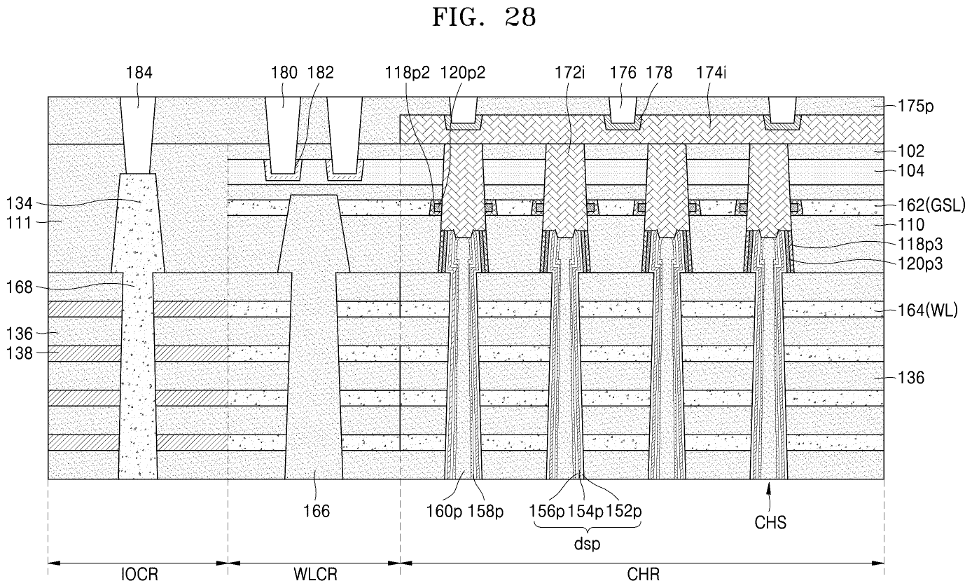

Referring to FIG. 28, a third contact hole 184 may be formed in the fourth insulating layer 111 on the fourth buried layer 134 of the input and output contact region IOCR and in the second interlayer insulating layer 175p. Furthermore, as illustrated in FIG. 4, the first metal contact plug 188 connected to the first semiconductor line 104 may be formed in the first contact hole 180. The first metal contact plug 188 may be connected to the first semiconductor line 104 through the first ohmic contact region 182.

The second metal contact plug 186 connected to the second semiconductor line 174i may be formed in the second contact hole 176. The second metal contact plug 186 may be connected to the second semiconductor line 174i through the second ohmic contact region 178.

The input and output contact plug 190 connected to the fourth buried layer 134 may be formed in the third contact hole 184. The first metal contact plug 188, the second metal contact plug 186, and the input and output contact plug 190 may be formed by the same process. The first metal contact plug 188, the second metal contact plug 186, and the input and output contact plug 190 may include a metal layer, for example, a tungsten layer. The vertical nonvolatile memory device 10 of FIGS. 4 and 5 may be manufactured through the manufacturing process described above.

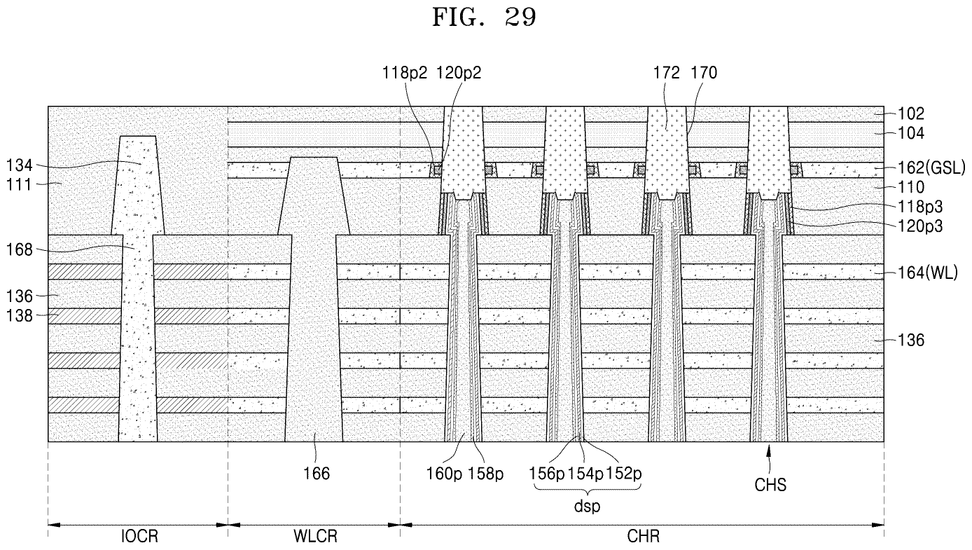

FIGS. 29 to 32 are cross-sectional views to describe a method of manufacturing a vertical nonvolatile memory device, according to an embodiment.

In detail, FIGS. 29 to 32 are cross-sectional views to describe the method of manufacturing the vertical nonvolatile memory device 10-1 of FIGS. 6 and 7. In FIGS. 29 to 32, the reference numerals that are the same or substantially the same as the reference numerals in FIGS. 6 and 7 indicate members that are the same or substantially the same as the members of FIGS. 6 and 7. In FIGS. 29 to 32, the aspects described with reference to FIGS. 6 and 7 are briefly described or are not described.

First, the manufacturing process of FIGS. 8 to 23 may be performed. By doing so, the channel exposure holes 170 may be formed in upper surfaces of the vertical channel structures CHS. The channel exposure holes 170 may expose the vertical channel pattern 158p by passing through the first semiconductor line 104 and the second gate line 162.

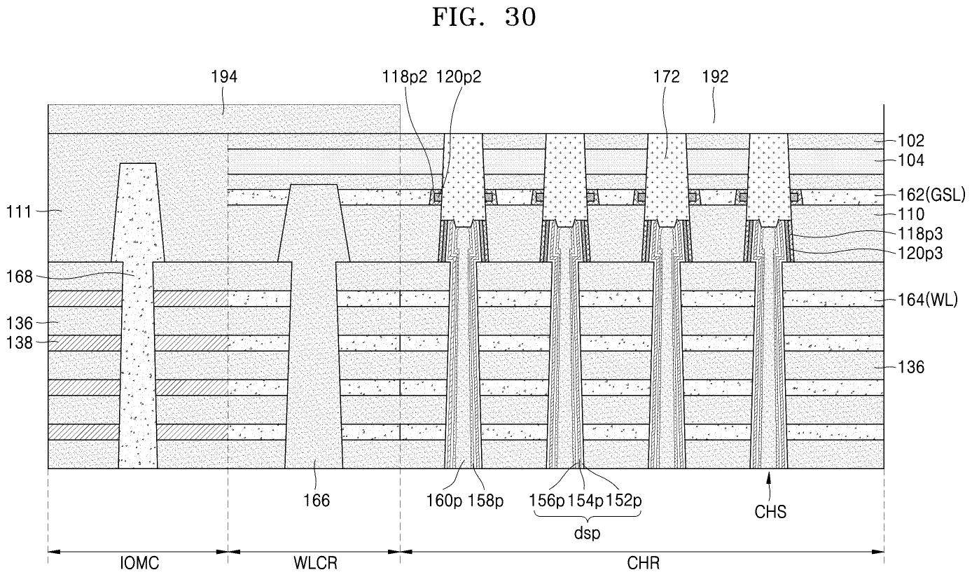

Referring to FIGS. 29 and 30, as illustrated in FIG. 29, the semiconductor contact plugs 172 buried in the channel exposure holes 170 on the vertical channel structure CHS may be formed. The semiconductor contact plugs 172 may be formed to be buried in the channel exposure holes 170 passing through the first semiconductor line 104 and the second gate line 162. The semiconductor contact plugs 172 may include a polysilicon layer not doped with impurities.

According to some embodiments, the semiconductor contact plugs 172 may be manufactured through a series of processes described below. That is, after forming, on the first insulating layer 102, a semiconductor material layer, for example, a polysilicon layer, to bury the channel exposure holes 170, a semiconductor material pattern may be formed only in the channel region CHR by using a photoetch process. Furthermore, the semiconductor material pattern may be chemically and mechanically polished with the first insulating layer 102 as an etching stopping layer, to form the semiconductor contact plugs 172 only in the channel exposure holes 170.

As illustrated in FIG. 30, a third interlayer insulating layer 194 having a plug exposure hole 192 exposing the semiconductor contact plugs 172 of the channel region CHR may be formed. The third interlayer insulating layer 194 may be formed only in the input and output contact region IOCR and the word line cut region WLCR by etching an interlayer insulating material layer by using a photoetch process after forming the interlayer insulating material layer on the semiconductor contact plugs 172 and the first insulating layer 102.

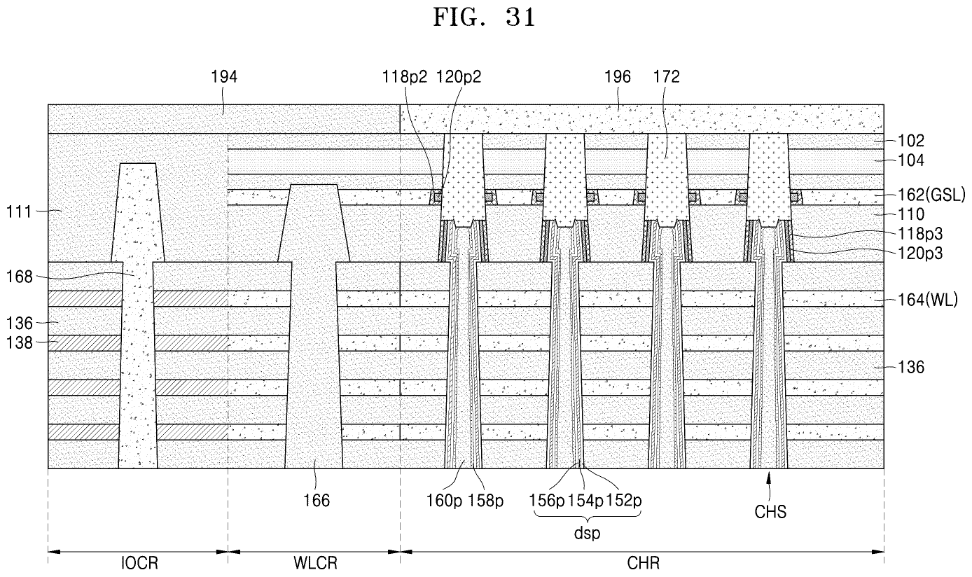

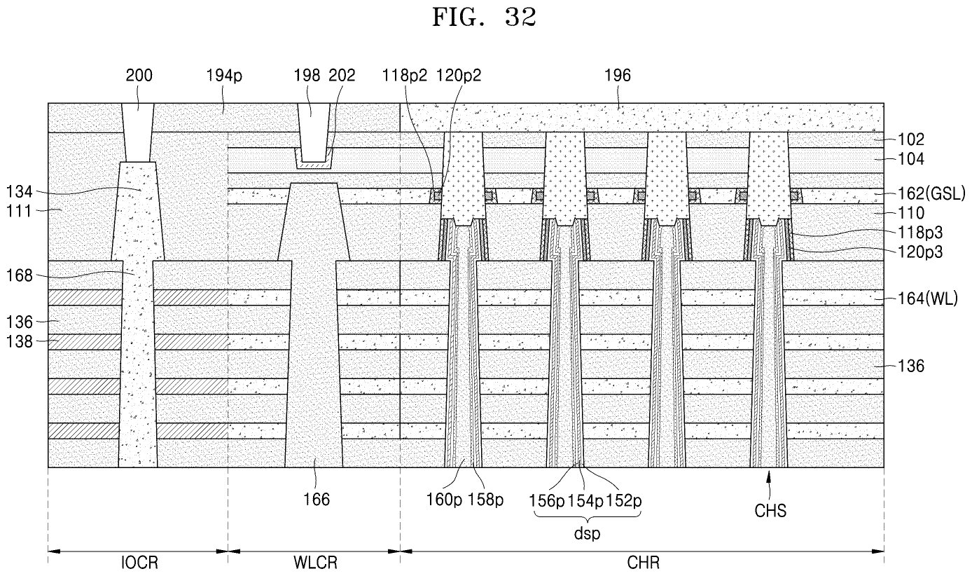

Referring to FIGS. 31 and 32, the metal line 196 connected to the semiconductor contact plugs 172 by being buried in the plug exposure hole 192 (see FIG. 30) may be formed as illustrated in FIG. 31. The metal line 196 may be formed to extend in the horizontal direction. The metal line 196 may include a metal layer, for example, a tungsten layer. The metal line 196 may be formed by chemically and mechanically polishing a metal material layer after forming the metal material layer on the third interlayer insulating layer 194 to bury the plug exposure hole 192 (see FIG. 30).

As illustrated in FIG. 32, a fourth contact hole 198 exposing the first semiconductor line 104 may be formed in the third interlayer insulating layer 194 on the first semiconductor line 104 of the word line cut region WLCR and in the first insulating layer 102. Next, the third ohmic contact region 202 of the first conductivity type, that is, N-type, may be formed in the fourth contact hole 198.

The third ohmic contact region 202 may be formed by injecting impurities of the first conductivity type, that is, N-type, in the first semiconductor line 104 of the first conductivity type in the fourth contact hole 198. A fifth contact hole 200 may be formed in the fourth insulating layer 111 on the fourth buried layer 134 of the input and output contact region IOCR and in the third interlayer insulating layer 194p.

Furthermore, as illustrated in FIG. 6, the third metal contact plug 204 connected to the first semiconductor line 104 may be formed in the fourth contact hole 198. The third metal contact plug 204 may be connected to the first semiconductor line 104 through the third ohmic contact region 202.

The fourth metal contact plug 206 connected to the fourth buried layer 134 may be formed in the fifth contact hole 200. The third metal contact plug 204 and the fourth metal contact plug 206 may be formed by the same process. The third metal contact plug 204 and the fourth metal contact plug 206 may include a metal layer, for example, a tungsten layer. Through the manufacturing process described above, the vertical nonvolatile memory device 10-1 of FIGS. 6 and 7 may be manufactured.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts has been particularly shown and described with reference to example embodiments thereof, it will be understood that various changes in form and details may be made therein without departing from the spirit and scope of the following claims.

What is claimed is:

1. A vertical nonvolatile memory device comprising:
a plurality of vertical channel structures extending in a vertical direction and apart from each other in a horizontal direction;
a plurality of first gate lines extending in the horizontal direction while surrounding the plurality of vertical channel structures, the plurality of first gate lines being apart from each other in the vertical direction, the plurality of first gate lines being configured as word lines;
a second gate line extending in the horizontal direction on the plurality of first gate lines, the second gate line being configured as a ground selection line;
a first semiconductor line of a first conductivity type, the first semiconductor line extending in the horizontal direction on the second gate line;
a plurality of semiconductor contact plugs of a second conductivity type, the plurality of semiconductor contact plugs being connected to the plurality of vertical channel structures by passing through the first semiconductor line and the second gate line;
a second semiconductor line of the second conductivity type, the second semiconductor line extending in the horizontal direction on the plurality of semiconductor contact plugs and being connected to the plurality of semiconductor contact plugs;
a first metal contact plug connected to the first semiconductor line; and
a second metal contact plug connected to the second semiconductor line.

2. The vertical nonvolatile memory device of claim 1, wherein
the first semiconductor line includes an N-type polysilicon layer, and
the plurality of semiconductor contact plugs and the second semiconductor line include P-type polysilicon layers.

3. The vertical nonvolatile memory device of claim 1, wherein
a stack structure including the plurality of first gate lines and the second gate line defines a word line cut region and a channel region defined by the word line cut region,
the plurality of vertical channel structures, the plurality of first gate lines, and the second gate line are in the channel region.

4. The vertical nonvolatile memory device of claim 3, wherein the first semiconductor line extends in the horizontal direction to the word line cut region.

5. The vertical nonvolatile memory device of claim 3, wherein the second semiconductor line is in the channel region.

6. The vertical nonvolatile memory device of claim 1, further comprising:
a gate dielectric layer of a ground selection transistor between the plurality of semiconductor contact plugs and the second gate line, wherein
the gate dielectric layer of the ground selection transistor is in a recess hole defined by a space between a side wall of the plurality of semiconductor contact plugs and the second gate line,
the recess hole is recessed toward the side wall of the plurality of semiconductor contact plugs and is between the plurality of semiconductor contact plugs and the second gate line.

7. The vertical nonvolatile memory device of claim 6, wherein the gate dielectric layer comprises a first gate dielectric pattern on an inner wall of the recess hole and a second gate dielectric pattern on the first gate dielectric pattern in the recess hole.

8. The vertical nonvolatile memory device of claim 7, wherein the second gate line and the gate dielectric layer are apart from the plurality of vertical channel structures in the vertical direction.

9. The vertical nonvolatile memory device of claim 1, wherein
the plurality of vertical channel structures comprise a data storage pattern, a vertical channel pattern, and a buried insulating pattern, which are sequentially formed on inner walls of channel holes passing through the plurality of first gate lines in the vertical direction.

10. The vertical nonvolatile memory device of claim 1, wherein
the first semiconductor line further includes a first ohmic contact region of the first conductivity type, and
the first metal contact plug is in the first ohmic contact region.

11. The vertical nonvolatile memory device of claim 1, wherein
the second semiconductor line further includes a second ohmic contact region of the second conductivity type, and
the second metal contact plug is arranged in the second ohmic contact region.

12. A vertical nonvolatile memory device comprising:
a plurality of vertical channel structures extending in a vertical direction and apart from each other in a horizontal direction;
a plurality of first gate lines extending in the horizontal direction while surrounding the plurality of vertical channel structures, the plurality of first gate lines being apart from each other in the vertical direction, and the plurality of first gate lines being configured as word lines;
a second gate line extending in the horizontal direction on the plurality of first gate lines, the second gate line being configured as a ground selection line;
a first semiconductor line of a first conductivity type, the first semiconductor line extending in the horizontal direction on the second gate line;
a plurality of semiconductor contact plugs connected to the plurality of vertical channel structures by passing through the first semiconductor line and the second gate line, and the plurality of semiconductor contact plugs not doped with impurities;
a first metal contact plug connected to the first semiconductor line; and
a metal line extending in the horizontal direction on the plurality of semiconductor contact plugs and connected to the plurality of semiconductor contact plugs.

13. The vertical nonvolatile memory device of claim 12, wherein
the first semiconductor line includes an N-type polysilicon layer, and
the plurality of semiconductor contact plugs include a polysilicon layer not doped with impurities.

14. The vertical nonvolatile memory device of claim 12, wherein
a stack structure including the plurality of first gate lines and the second gate line defines a word line cut region and a channel region defined by the word line cut region,
the plurality of vertical channel structures, the plurality of first gate lines, and the second gate line are in the channel region, and
the first semiconductor line extends in the horizontal direction and in the word line cut region.

15. The vertical nonvolatile memory device of claim 12, further comprising:
a gate dielectric layer of a ground selection transistor between the plurality of semiconductor contact plugs and the second gate line,
the gate dielectric layer of the ground selection transistor is in a recess hole defined by a space between a side wall of the plurality of semiconductor contact plugs and the second gate line,
the recess hole is recessed toward the side wall of the plurality of semiconductor contact plugs and is between the plurality of semiconductor contact plugs and the second gate line,
wherein the gate dielectric layer comprises a first gate dielectric pattern on an inner wall of the recess hole and a second gate dielectric pattern on the first gate dielectric pattern in the recess hole.

16. The vertical nonvolatile memory device of claim 12, wherein the plurality of vertical channel structures comprise a data storage pattern, a vertical channel pattern, and a buried insulating pattern, which are sequentially formed on inner walls of channel holes passing through the plurality of first gate lines in the vertical direction.

17. The vertical nonvolatile memory device of claim 12, wherein
the first semiconductor line includes a first ohmic contact region of the first conductivity type, and
the first metal contact plug is in the first ohmic contact region.

18. A vertical nonvolatile memory device comprising:
a plurality of vertical channel structures extending in a vertical direction and spaced apart from each other in a horizontal direction;
a plurality of first gate lines extending in the horizontal direction while surrounding the plurality of vertical channel structures, the plurality of first gate lines being apart from each other in the vertical direction, and the plurality of first gate lines being configured as word lines;
a second gate line extending in the horizontal direction on the plurality of first gate lines, the second gate line being spaced apart from the plurality of vertical channel structures in the vertical direction and configured as a ground selection line;
a first semiconductor line of a first conductivity type, the first semiconductor line extending in the horizontal direction on the second gate line, the first semiconductor line including a first ohmic contact region;
a plurality of semiconductor contact plugs of a second conductivity type, the plurality of semiconductor contact plugs connected to the plurality of vertical channel structures by passing through the first semiconductor line and the second gate line;
a gate dielectric layer of a ground selection transistor in a recess hole recessed toward a side wall of the plurality of semiconductor contact plugs, the recess hole being defined by a space between the side wall of the plurality of semiconductor contact plugs and the second gate line;
a second semiconductor line of the second conductivity type, the second semiconductor line extending in the horizontal direction on the plurality of semiconductor contact plugs and being apart from the first semiconductor line in the vertical direction, the second semiconductor line being connected to the plurality of semiconductor contact plugs, the second semiconductor line including a second ohmic contact region;
a first metal contact plug connected to the first semiconductor line through the first ohmic contact region; and
a second metal contact plug connected to the second semiconductor line through the second ohmic contact region.

19. The vertical nonvolatile memory device of claim 18, wherein
the first semiconductor line includes an N-type polysilicon layer, and
the plurality of semiconductor contact plugs and the second semiconductor line include P-type polysilicon layers.

20. The vertical nonvolatile memory device of claim 18, wherein the gate dielectric layer comprises a first gate dielectric pattern on an inner wall of the recess hole and a second gate dielectric pattern on the first gate dielectric pattern in the recess hole.
